(19) United States
(12) Patent Application Publication
(10) Pub. No.: US 2024/0147684 A1
(43) Pub. Date: May 2, 2024

(54) SEMICONDUCTOR STRUCTURE AND MANUFACTURING METHOD THEREOF

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/153,890

(22) Filed: Jan. 12, 2023

Related U.S. Application Data
(60) Provisional application No. 63/381,290, filed on Oct. 27, 2022.

(51) Int. Cl. H10B 10/00; G11C 11/412; G11C 11/417

(52) U.S. Cl. CPC H10B 10/12; G11C 11/412; G11C 11/417; H10B 10/18

(57) ABSTRACT

A method includes forming a static random access memory (SRAM) array comprising a plurality of SRAM cells, at least one of the SRAM cells comprising first and second pull-up transistors, first and second pull-down transistors, and first and second pass-gate transistors; forming a first front-side metal layer above the SRAM array, the first front-side metal layer comprising a first power supply voltage line and a bit-line, the first power supply voltage line electrically coupled to the first and second pull-up transistors, and the bit-line electrically coupled to the first pass-gate transistor; forming a back-side butt contact extending from a back-side of a gate structure of the first pull-up transistor to a back-side of a source/drain region of the second pull-up transistor from a cross sectional view.

### PRIORITY CLAIM AND CROSS-REFERENCE

This application claims priority to U.S. Provisional Application Ser. No. 63/381,290, filed Oct. 27, 2022, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are schematic views of a wafer including a front-side interconnect structure and a back-side interconnect structure on a device region thereof in accordance with some embodiments of the present disclosure.

FIGS. 2A and 2B illustrate a cell layout diagram of a circuit on a front-side and a back-side of a semiconductor structure, respectively, according to some embodiments of the present disclosure.

FIGS. 3A to 3F illustrate cross-sectional views obtained from reference cross-section C1-C1′, C2-C2′, C3-C3′, C4-C4′, C5-C5′, and C6-C6′ in FIGS. 2A and 2B.

FIGS. 4A and 4B illustrate a cell layout diagram of a circuit on a front-side and a back-side of a semiconductor structure, respectively, according to some embodiments of the present disclosure.

FIGS. 5A and 5B illustrate a cell layout diagram of a circuit on a front-side and a back-side of a semiconductor structure, respectively, according to some embodiments of the present disclosure.

FIGS. 6A-6E are top views of cell arrays according to some embodiments of the present disclosure.

FIGS. 7A and 7B illustrate enlarged views of an edge tap region in FIG. 6A and including CVdd tap structures on a front-side and a back-side of a semiconductor structure, respectively, according to some embodiments of the present disclosure.

FIGS. 7C and 7D illustrate cross-sectional views of a CVdd tap structure and a bit-line tap structure according to some embodiments of the present disclosure.

FIGS. 8A to 23C illustrate cross-sectional views of intermediate stages in the formation of a semiconductor structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. Therefore, the present disclosure in various embodiments provides a metal line routing method to improve the functional density and operation performance on the IC structure. Specifically, the front-side M1 level may include bit-line, bit-line-bar, and power supply voltage line. On the other hands, the front-side M1 level may be free of word-line. Therefore, the bit-line and bit-line-bar can be disposed in a lower metal layer to lower the resistance and the capacitance of the SRAM cell, such that the speed of SRAM cell can be improved.

In addition, the power supply voltage line (CVdd) located on wafer front-side is connected to power supply voltage line located on wafer back-side through a tapping structure located within an edge cell of the SRAM cell array, and further connected to chip bond pads located on wafer back-side rather than on wafer front-side, such that IR drop of the IC structure can be reduced. Furthermore, the butt contacts connecting the source/drain region and the gate electrode layer can be disposed on wafer back-side, and thus the back-side butt contacts can be fabricated simultaneously with back-side conductive via in a same process, and thus fabrication of the back-side butt contacts will not result in additional processes and hence additional cost and without additional metal materials and masks.

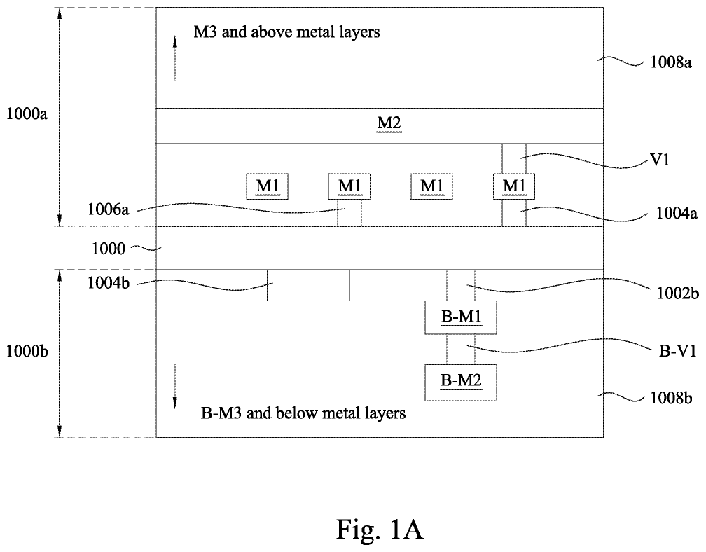

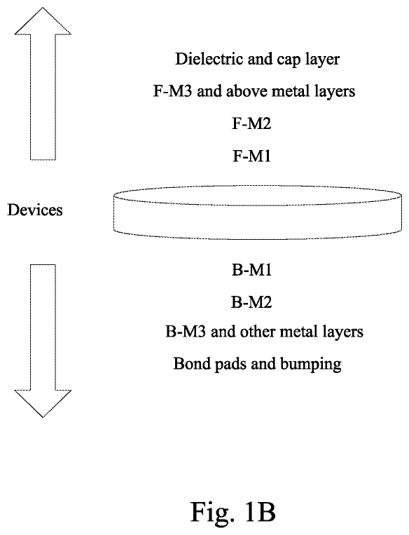

Reference is made to FIGS. 1A and 1B. FIGS. 1A and 1B are schematic views of a wafer including a front-side interconnect structure and a back-side interconnect structure on a device region thereof in accordance with some embodiments of the present disclosure. As shown in FIGS. 1A and 1B, a device region 1000 (see FIG. 1A) is provide in the wafer W and includes, such as gate, channel, and source/drain regions. A front-side interconnect structure 1000a is formed after the device region formation. Specifically, the front-side interconnect structure 1000a is formed to have a front-side gate via 1006a, and a front-side source/drain via 1004a. The front-side interconnect structure 1000a may further include, for example, two metallization layers, labeled as M1 and M2, with one layer of metallization via or interconnect, labeled as V1. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure 1000a includes a full metallization stack, including a portion of each of metallization layers M1 and M2 connected by the interconnect V1, with the front-side gate via 1006a, and the front-side source/drain via 1004a connecting the stack to the source/drain region and the gate of the transistor in the device region 1000. As shown in FIG. 1B, a dielectric structure and a cap layer may be further formed over the front-side interconnect structure 1000a. Also included in the front-side interconnect structure 1000a shown in FIG. 1A is a front-side IMD (inter-metal dielectric) layer 1008a. The front-side IMD layer 1008a may provide electrical insulation as well as structural support for the various features in the front-side interconnect structure 1000a.

As shown in FIGS. 1A and 1B, a back-side interconnect structure 1000b (see FIG. 1A) is formed after device region formation. Specifically, a back-side interconnect structure 1000b is formed to have a back-side via 1002b and a back-side contact 1004b. In some embodiments, the back-side contact 1004b can be a back-side butt contact connecting a source/drain region and a gate structure of a transistor in the device region 1000. The back-side interconnect structure 1000b may further include, for example, two metallization layers, labeled as B-M1 and B-M2, with one layer of metallization via or interconnect, labeled as B-V1. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure includes a full metallization stack, including a portion of each of metallization layers B-M1 and B-M2 connected by interconnect B-V1, with the back-side via 1002b and the back-side contact 1004b connecting the stack to the source/drain region and the gate structure of the transistor in the device region 1000. As shown in FIG. 1B, a plurality of bond pads may be further formed over the back-side interconnect structure 1000b. Also included in the back-side interconnect structure 1000b shown in FIG. 1A can be a back-side IMD layer 1008b. The back-side IMD layer 1008b may provide electrical insulation as well as structural support for the various features in the back-side interconnect structure 1000b.

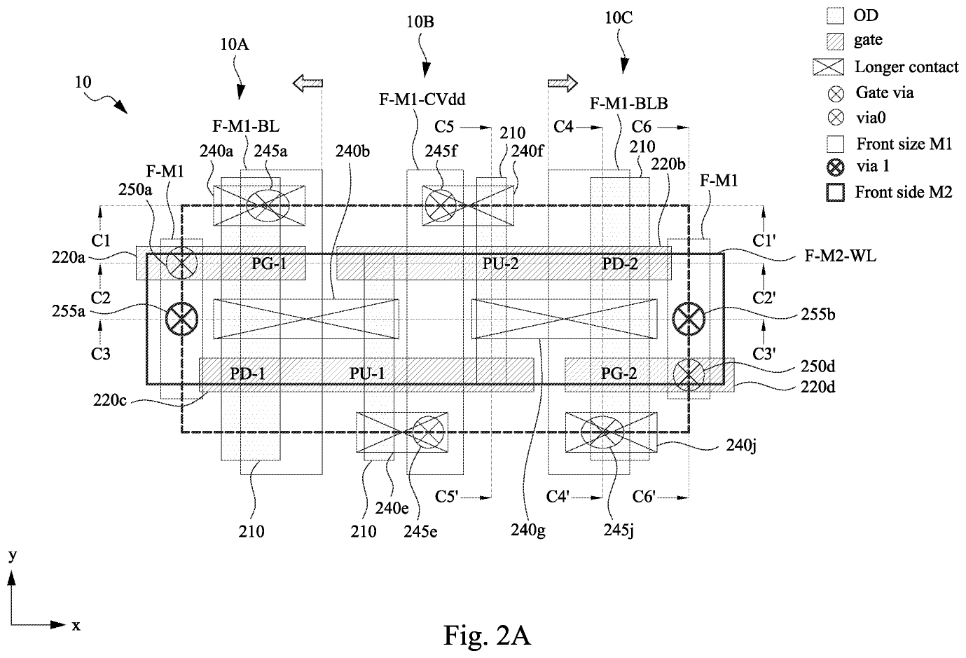

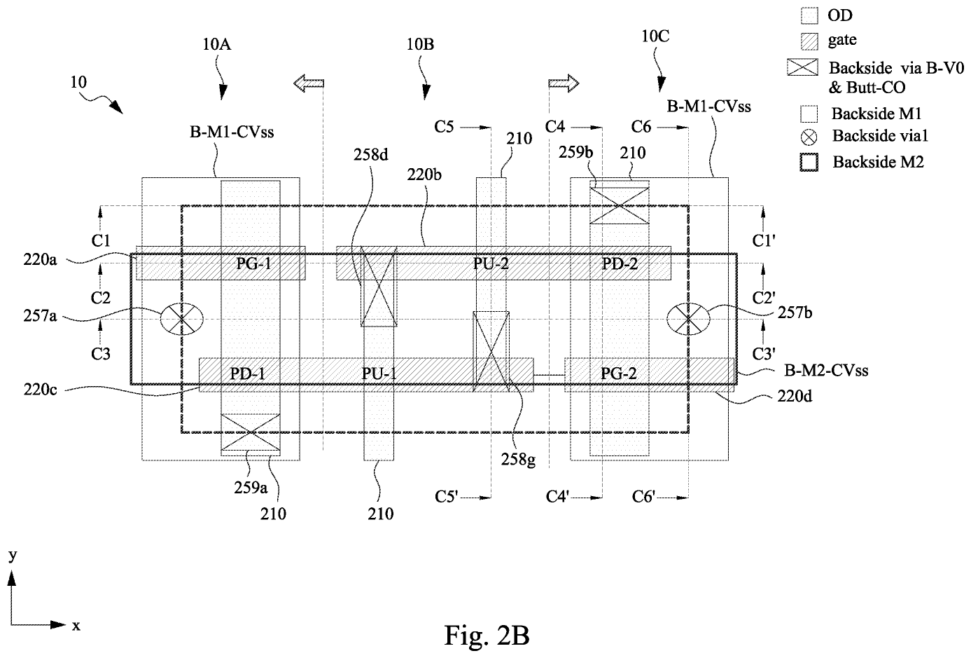

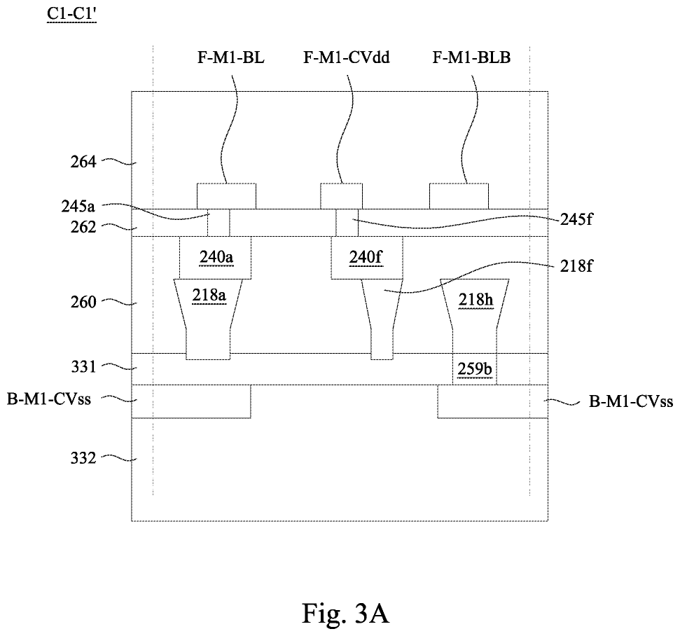

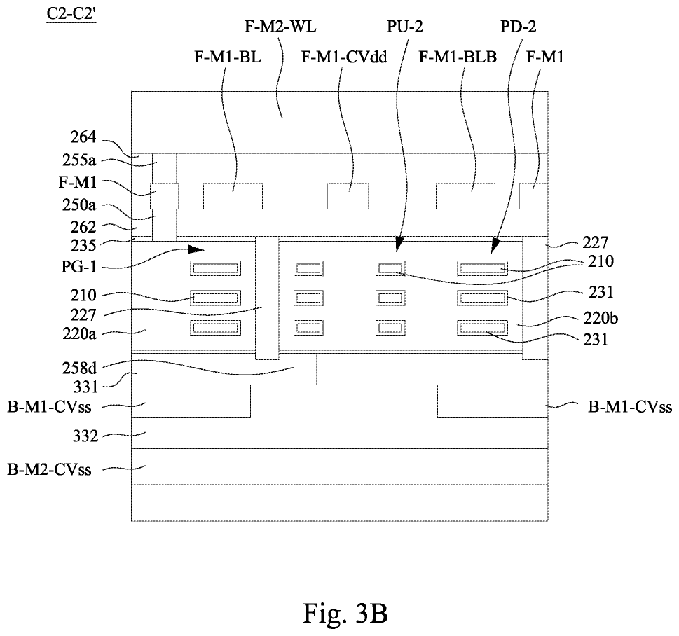

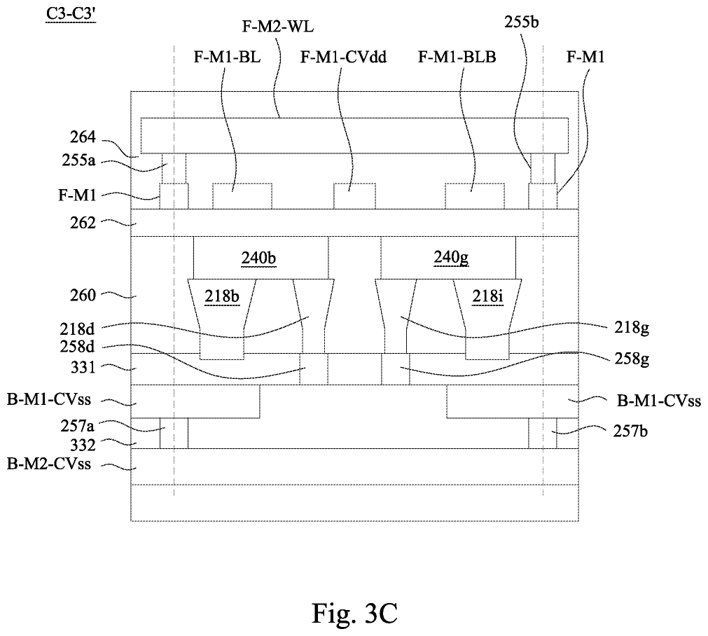

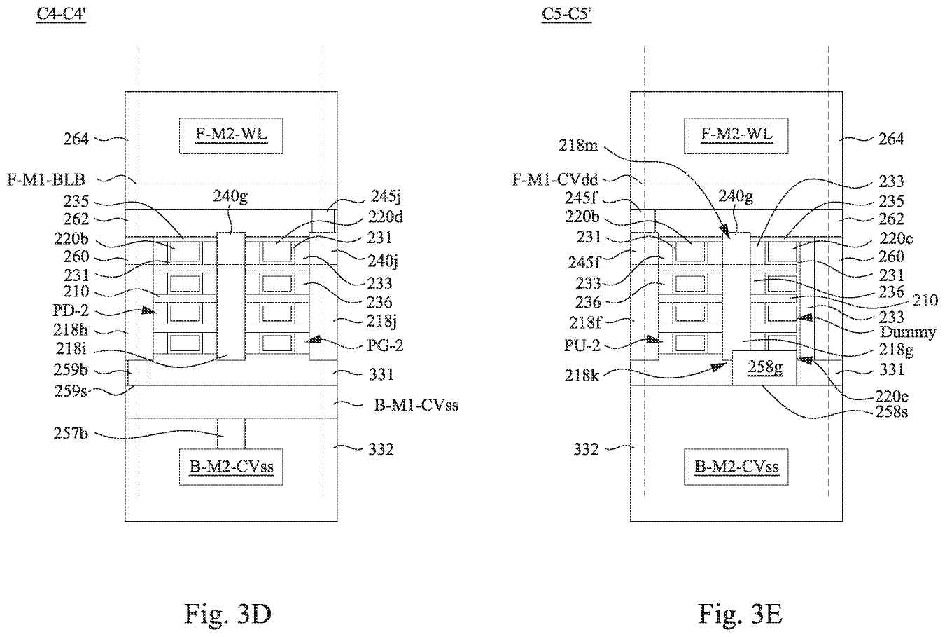

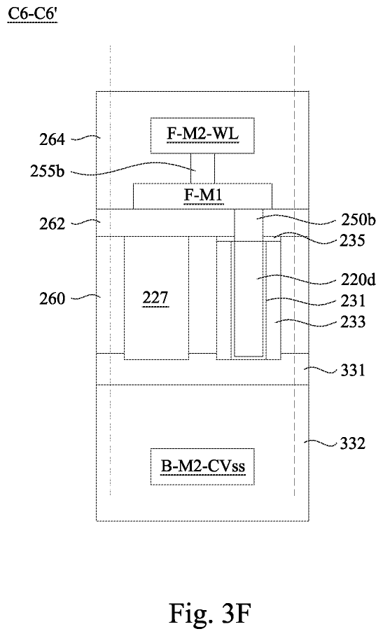

Reference is made to FIGS. 2A and 2B. FIGS. 2A and 2B illustrate a static random access memory (SRAM) cell layout diagram of a circuit on a front-side and a back-side of a semiconductor structure, respectively, according to some embodiments of the present disclosure. FIGS. 3A to 3F illustrate cross-sectional views obtained from reference cross-section C1-C1′, C2-C2′, C3-C3′, C4-C4′, C5-C5′, and C6-C6′ in FIGS. 2A and 2B. As shown in FIGS. 2A and 2B, an outer boundary the SRAM cell unit 10 is illustrated using a dashed line. In FIGS. 2A and 2B, it should be noted that the configuration of the SRAM cell unit 10 in the circuit is used as an illustration, and not to limit the disclosure. In some embodiments, the SRAM cell unit 10 may include first conductivity type device regions 10A and 10C, and a second conductivity type device region 10B between the first conductivity type device regions 10A and 10C. In some embodiments, the SRAM cell unit 10 may include a pass-gate transistor PG-1 and a pull-down transistor PD-1 in the first conductivity type device region 10A, a pass-gate transistor PG-2 and a pull-down transistor PD-2 in the first conductivity type device region 10C, and pull-up transistors PU-1 and PU-2 in the second conductivity type device region 10B. In some embodiments, the transistors PU-1 and PD-1 form a first inverter. The transistors PU-2 and PD-2 form a second inverter electrically cross coupled with the first inverter. The input of the first inverter is connected to transistor PG-1. The output of the first inverter is connected to the input of the second inverter. In some embodiments, the transistors PG-1, PG-2, PD-1, and PD-2 may be NMOS transistors on the first conductivity type device regions 10A and 10C being p-well regions, and the transistors PU-1 and PU-2 may be PMOS transistors on the second conductivity type device region 10B being an n-well region. In some embodiments, the transistors PG-1, PG-2, PD-1, PD-2, PU-1, and/or PU-2 may be with silicon channel regions. In some embodiments, the transistors PG-1, PG-2, PD-1, PD-2, PU-1, and/or PU-2 may be GAA FETs. As shown in FIGS. 2A and 2B, the silicon channel regions of the NMOS and PMOS transistors are formed by semiconductor sheets 210. The semiconductor sheets 210 are stacked along the Z-direction (not shown) and are wrapped by the corresponding gate electrode layers 220a, 220b, 220c, and 220d, and the Z-direction is perpendicular to the plane formed by the X-direction and Y-direction. In some embodiments, semiconductor sheets 210 each has a length extending along Y-direction from a top view. The SRAM cell unit 10 may further include gate electrode layers 220a, 220b, 220c, and 220d extending in the X-direction and across the corresponding semiconductor sheets 210. In some embodiments, the gate electrode layers 220a, 220b, 220c, and 220d can be interchangeably referred to gate patterns, gate strips, gate electrodes, or gate layers.

As shown in FIG. 2A illustrating the SRAM cell unit 10 on the front-side of the semiconductor structure, the gate electrode layers 220a and 220d are connected to an overlying level (e.g., front-side metal layer F-M1) through gate vias 250a and 250d. In some embodiments, a source/drain region 218a (see FIG. 3A) of the transistor PG-1 is electrically coupled to an overlying level (e.g., bit-line F-M1-BL) through a corresponding source/drain contact 240a and a corresponding source/drain via 245a. In some embodiments, the source/drain region 218a as shown in FIG. 3A electrically coupled to a bit-line F-M1-BL can be interchangeably referred to a bit-line node. A share source/drain region 218b (see FIG. 3C) of the transistors PG-1 and PD-1 are electrically coupled to another share source/drain region 218d (see FIG. 3C) of the transistors PU-1 and PU-2 through a source/drain contact 240b. A source/drain region of the transistor PU-1 is electrically coupled to an overlying level (e.g., power supply voltage line F-M1-CVdd) through a corresponding source/drain contact 240e and a corresponding source/drain via 245e. SRAM cell can be powered through a positive power supply node CVdd (also denoted as Vdd) that has a positive power supply voltage. In some embodiments, the power supply voltage line F-M1-CVdd can be interchangeably referred to a power mesh conductor or a CVdd conductor. A source/drain region (see FIGS. 3A and 3E) of the transistor PU-2 is electrically coupled to an overlying level (e.g., power supply voltage line F-M1-CVdd) through a corresponding source/drain contact 240f and a corresponding source/drain via 245f. In some embodiments, the source/drain regions electrically coupled to the power supply voltage lines F-M1-CVdd can be interchangeably referred to CVdd nodes. A share source/drain region 218g (see FIGS. 3C and 3E) of the transistors PU-1 and PU-2 are electrically coupled to another share source/drain region 218i (see FIG. 3C) of the transistors PD-1 and PG-2 through a source/drain contact 240g. In some embodiments, a source/drain region 218j (see FIG. 3D) of the transistor PG-2 is electrically coupled to an overlying level (e.g., bit-line-bar F-M1-BLB) through a corresponding source/drain contact 240j and a corresponding source/drain via 245j. In some embodiments, the source/drain region 218j electrically coupled to the bit-line-bar F-M1-BLB can be interchangeably referred to a bit-line-bar node. In some embodiments, the source/drain regions 218a, 218b, 218g, 218i, and 218j can be interchangeably referred to source/drain patterns or epitaxial structures. In some embodiments, the source/drain contact 240a, 24b, 240e, 240f, 240g, and 240j can be interchangeably referred to longer contacts having longitudinal axes extending in lengthwise directions of the gate electrode layers 220a, 220b, 220c, and 220d.

Throughout the description, the notations of metal lines may be followed by the metal line levels they are in, wherein the respective metal line level is placed in parenthesis. As shown in FIG. 2A, metal lines disposed at the M1 level on the front-side of the semiconductor structure may include the bit-line F-M1-BL, the bit-line-bar F-M1-BLB, and the power supply voltage lines F-M1-CVdd laterally between the bit-line F-M1-BL and the bit-line-bar F-M1-BLB. That is, the bit-line F-M1-BL, the bit-line-bar F-M1-BLB, and the power supply voltage lines F-M1-CVdd are at a same level height. The metal lines disposed at the M1 level on the front-side of the semiconductor structure may have lengthwise directions parallel to the Y-direction (e.g., column direction). Accordingly, each of these metal lines disposed at the M1 level on the front-side of the semiconductor structure may extend into, and may be connected to, a plurality of SRAM cells in the same column. In some embodiments, the power supply voltage line F-M1-CVdd disposed at the M1 level can be interchangeably referred to a power supply voltage landing pad or a power supply voltage landing line, the bit-line F-M1-BL disposed at the M1 level can be interchangeably referred to a bit-line landing pad or a bit-line landing line, and the bit-line-bar F-M1-BLB disposed at the M1 level can be interchangeably referred to a write bit-line-bar landing pad or a write bit-line-bar landing line. In some embodiments, the front-side M1 level may be free of word-lines. As shown in FIG. 2A, metal lines disposed at the M2 level overlying the front-side M1 level may include a word-line F-M2-WL. The M2 level is at a higher level height than the M1 level. The metal lines disposed at the M2 level on the front-side of the semiconductor structure may have lengthwise directions parallel to the X-direction (e.g., row direction). Accordingly, each of these metal lines disposed at the M2 level on the front-side of the semiconductor structure may extend into, and may be connected to, a plurality of SRAM cell units 10 in the same row. The front-side metal layers F-M1 are connected to an overlying level (e.g., word-line F-M2-WL) through vias 255a, 255b (see FIG. 3F). In some embodiments, the front-side M2 level may be free of power supply voltage lines. In some embodiments, the front-side M2 level may be free of bit-lines and bit-line-bars. In some embodiments, the bit-line F-M2-WL disposed at the M2 level on the front-side of the semiconductor structure can be interchangeably referred to a word-line landing pad or a word-line landing line. In some embodiments, the lines can be interchangeably referred to metal layers, conductive lines, conductive layers, or conductors.

As shown in FIG. 2B illustrating the SRAM cell unit 10 on the back-side of the semiconductor structure, the gate electrode layers 220b and 220c are connected to adjacent source/drain regions 218d and 218g through butt contacts 258d and 258g. In some embodiments, the butt contacts 258d and 258g can be interchangeably referred to butt connection structures. In other words, the back-side butt contact 258g extends from a back-side 220e (see FIG. 3E) of the gate electrode layer 220c of the transistor PU-1 to a back-side 218k (see FIG. 3E) of the source/drain region 218g (see FIG. 3E) of the transistor PU-2, and the back-side butt contact 258d extends from a back-side of the gate electrode layer 220b of the transistor PU-2 to a back-side of the source/drain region of the transistor PU-1 from the cross sectional view. In greater detail, as shown in FIG. 3E, the back-side butt contact 258g is on the back-side 218k of the source/drain region 218g opposite to the front-side source/drain contact 240g on a front-side 218m of the source/drain region 218g from the cross sectional view. In some embodiment, because the back-side butt contact 258g (see FIG. 3E) can be fabricated simultaneously with the back-side conductive via 259b (see FIG. 3D) in a same deposition process and a same planarization process, a back-side surface 258s of the back-side butt contact 258g (see FIG. 3E) may be level with a back-side surface 259s of the back-side conductive via 259b (see FIG. 3D), of which the back-side surface 258s of the back-side butt contact 258g and the back-side surface 259s of the back-side conductive via 259b both face away from the semiconductor sheets 210. A source/drain region of the transistor PD-1 is electrically coupled to an underlying level (e.g., power supply voltage line B-M1-CVss) through a corresponding conductive via 259a. The SRAM cell can be connected to power supply voltage CVss (also denoted as VSS), which may be an electrical ground. In some embodiments, the power supply voltage line B-M1-CVss can be interchangeably referred to a power mesh conductor. A source/drain region 218h (see FIGS. 3A and 3D) of the transistor PD-2 is electrically coupled to an underlying level (e.g., power supply voltage CVss) through a corresponding via 259b. In some embodiments, the source/drain regions as shown in FIG. 2B coupled to the power supply voltage lines B-M1-CVss can be interchangeably referred to power supply voltage nodes.

Throughout the description, the notations of metal lines may be followed by the metal line levels they are in, wherein the respective metal line level is placed in parenthesis. As shown in FIG. 2B, metal lines disposed at the M1 level on the back-side of the semiconductor structure may include the power supply voltage lines B-M1-CVss. The metal lines disposed at the M1 level on the back-side of the semiconductor structure may have lengthwise directions parallel to the Y-direction (e.g., column direction). Accordingly, each of these metal lines disposed at the M1 level on the back-side of the semiconductor structure may extend into, and may be connected to, a plurality of SRAM cell units 10 in the same column. In some embodiments, the power supply voltage line B-M1-CVss disposed at the M1 level on the back-side of the semiconductor structure can be interchangeably referred to a power supply voltage landing pad or a power supply voltage landing line. As shown in FIG. 2B, metal lines disposed at the M2 level underlying the back-side M1 level may include a power supply voltage line B-M2-CVss. The metal lines disposed at the M2 level on the back-side of the semiconductor structure may have lengthwise directions parallel to the X-direction (e.g., row direction). Accordingly, each of these metal lines disposed at the M2 level on the back-side of the semiconductor structure may extend into, and may be connected to, a plurality of SRAM cell units 10 in the same row. The power supply voltage line B-M1-CVss are connected to an underlying level (e.g., power supply voltage line B-M2-CVss) through vias 257a, 257b. In some embodiments, the lines can be interchangeably referred to metal layers, conductive lines, conductive layers, or conductors.

The present disclosure provides a metal line routing method. The front-side M1 level may include bit-line F-M1-BL, bit-line-bar F-M1-BLB, and power supply voltage line F-M1-CVdd. On the other hands, the front-side M1 level may be free of word-line and power supply voltage line CVss. Therefore, the bit-line and bit-line-bar can be disposed in a lower metal layer to lower the resistance and the capacitance of the SRAM cell, such that the speed of SRAM cell can be improved. In addition, the power supply voltage line CVdd located on front-side is connected to power supply voltage line CVdd located on back-side through a tapping structure located within an edge cell of the SRAM cell array, and further connected to chip bond pads located on wafer back-side other than on wafer front-side, such that IR drop of the IC structure can be reduced. The back-side chip bumping scheme can save one-time protection layer formation on the wafer front-side, which in turn allows for reducing the process cost. In some embodiments, the front-side M2 level may only serve for word-line WL to have a wider width thereof, such that RC delay of the semiconductor structure can be improved.

In other words, some of the conductive features (e.g., butt contact, power supply voltage line CVss) can be moved from the wafer front-side to the wafer back-side to achieve a capability for cell scaling down and RC reduction. For example, the butt contacts 258d and 258g can be disposed on wafer back-side to connect the source/drain region and the gate electrode layer. The back-side butt contacts 258d and 258g can be fabricated simultaneously with back-side conductive via in a same process, and thus fabrication of the back-side butt contacts 258d and 258g will not result in additional processes and hence additional cost and without additional metal materials and masks. Moreover, the power supply voltage lines B-M1-CVss and B-M1-CVss can be disposed on wafer back-side to have a wider width thereof, such that IR drop of the semiconductor structure can be reduced. Further, a metal pitch of power supply voltage lines B-M1-CVss and B-M2-CVss in each level can also be enlarged, such that the back-side power supply voltage line CVss with enlarging metal line pitch can be formed by a single lithography patterning, which in turn reduces the manufacturing cost.

In some embodiments, the layouts as shown in FIGS. 2A and 2B are represented by a plurality of masks generated by one or more processors and/or stored in one or more non-transitory computer-readable media. Other formats for representing the layout are within the scope of various embodiments. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

In FIGS. 3A, 3C, 3D, and 3E, the source/drain regions 218a, 218b, 218h, 218i, and 218j of the transistors PG-1, PG-2, PD-1, and PD-2 may include SiP, SiC, SiPC, SiAs, Si, or a combination thereof. In some embodiments, the phosphorus atomic concentration (or arsenic, or both) of the source/drain regions 218a, 218b, 218h, 218i, and 218j may be within a range of 2E19/cm³ to about 3E21/cm³. In some embodiments, the source/drain regions 218d, 218f, and 218g of the transistors PU-1 and PU-2 may include boron-doped SiGe, boron-doped SiGeC, boron-doped Ge, boron-doped Si, or combinations thereof. In some embodiments, the boron atomic concentration of the source/drain regions 218d, 218f, and 218g may be within a range of 1E19/cm³ to about 6E20/cm³. In some embodiments, the Ge atomic concentration of the source/drain regions is within a range of about 36% to about 85%.

In FIGS. 3D, 3E, and 3F, gate spacers 233 are formed on the sidewalls of the gate electrode layers 220a, 220b, 220c, and 220d. In some embodiments, the gate spacer 233 may be made of silicon nitride or silicon oxynitride, although any suitable material, such as low-dielectric constant (low-k) materials having a k-value less than about 3.5, may be utilized. Inner spacers 236 can act as isolation features and may be formed between the source/drain regions 218a, 218b, 218d, 218f, 218g, 218h, 218i, and 218j and the gate electrode layers 220a, 220b, 220c, and 220d. In some embodiments, the inner spacers 236 can be interchangeably referred to lower gate spacers. In some embodiments, the inner spacers 236 may have a lateral dimension in a range from about 4 nm to about 12 nm. In some embodiments, the inner spacers 236 may be made of silicon nitride or silicon oxynitride, although any suitable material, such as low-dielectric constant (low-k) materials having a k-value less than about 3.5, may be utilized. In some embodiments, the inner spacers 236 may be air gaps. In some embodiments, the inner spacer 236 may have a higher K (dielectric constant) value than the gate spacer 233.

In FIGS. 3B and 3E-3F, hard mask layers 235 are formed over the gate electrode 220a, 220b, 220c, and 220d. In some embodiments, the hard mask layer 235 can be interchangeably referred to a gate top dielectric. In some embodiments, the hard mask layer 235 may be made of dielectric material, such as SiO₂, Si₃N₄, SiON, SiOC, SiOCN base dielectric material, or combinations thereof. In FIG. 3B, the dielectric regions 227 are formed on opposite ends of the gate electrode layers 220a through 220d. In some embodiments, each dielectric region 227 is a gate-cut structure for the gate structure, and the gate-cut structure is formed by a cut metal gate (CMG) process.

In FIGS. 3A to 3F, an inter-layer dielectric (ILD) layer 260 is formed between the gate electrode layers 220a, 220b, 220c, and 220d and over the source/drain regions 218a, 218b, 218d, 218f, 218g, 218h, 218i, and 218j. An ILD layer 262 is formed over the hard mask layers 235 and the ILD layer 260 and laterally surrounds the gate vias 250a and 250d and the source/drain via 245a, 245e, 245f, and 245j. An inter-metal dielectric (IMD) layer 264 is formed over the ILD layer 262 and can provide electrical insulation as well as structural support for the various features therein, such as the power supply voltage lines F-M1-CVdd, the bit-line F-M1-BL, the bit-line-bar F-M1-BLB, and word-line F-M2-WL. In some embodiments, the ILD layer 260, the ILD layer 262, and/or the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

In FIGS. 3A to 3F, the back-side dielectric 331 and an IMD layer 332 are deposited over the source/drain regions 218a, 218b, 218g, 218i, and 218j in sequence. The butt contacts 258d, 258g and conductive vias 259a, 259b are formed in the back-side dielectric 331. The power supply voltage lines B-M1-CVss, B-M2-CVss are formed in the IMD layer 332. The back-side dielectric 331 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. The IMD layer 332 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

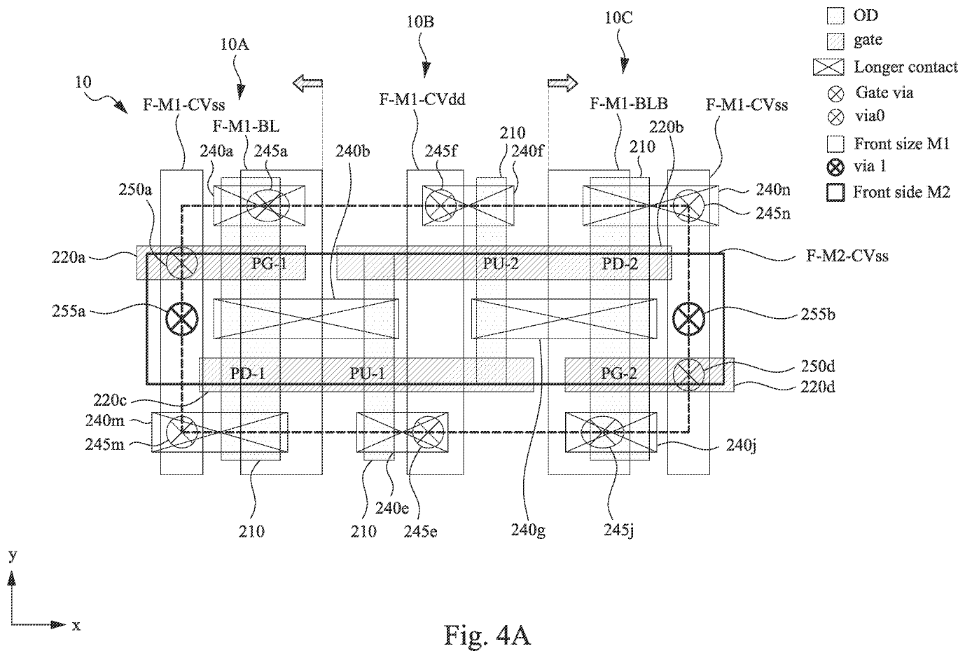

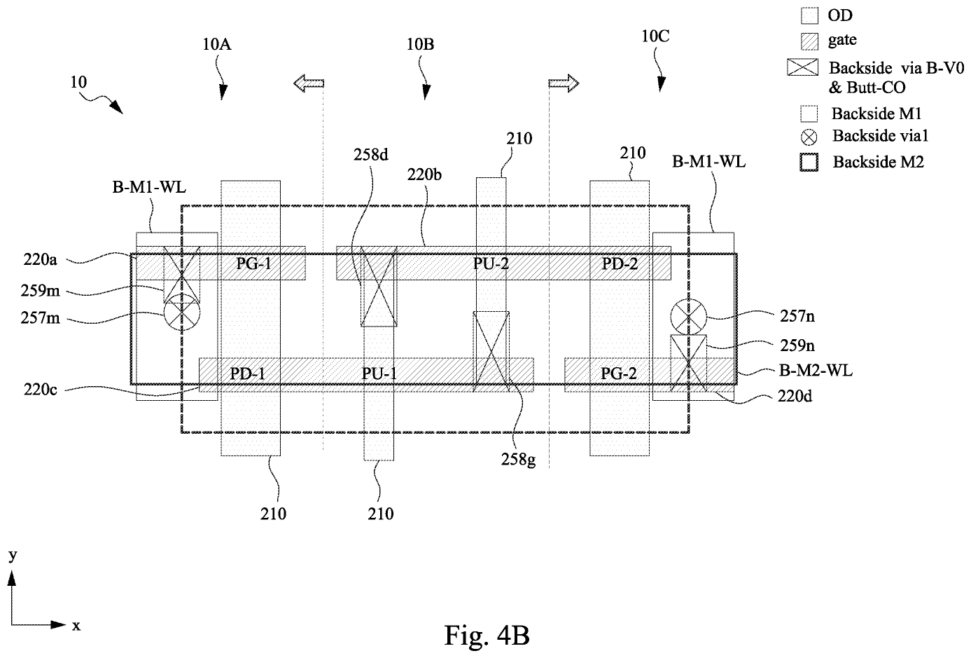

Reference is made to FIGS. 4A and 4B. FIGS. 4A and 4B illustrate a SRAM cell layout diagram of a circuit on a front-side and a back-side of a semiconductor structure, respectively, according to some embodiments of the present disclosure. While FIGS. 4A and 4B show an embodiment of the semiconductor structure with a different metal line routing method than the semiconductor structure in FIGS. 2A-3F. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 4A and 4B, the front-side M1 level may include bit-line F-M1-BL, bit-line-bar F-M1-BLB, and power supply voltage lines F-M1-CVdd, F-M1-CVss. On the other hands, the front-side M1 level may be free of word-line. In some embodiments, the front-side M1 and M2 levels both are free of word-lines. Therefore, the bit-line F-M1-BL and bit-line-bar F-M1-BLB can be disposed in a lower metal layer to lower the resistance and the capacitance of the SRAM cell, such that the speed of SRAM cell can be improved. In some embodiments, the front-side M2 level may include a power supply voltage line CVss. In addition, the power supply voltage lines CVdd, CVss located on front-side are connected to power supply voltage lines CVdd, CVss located on back-side through tapping structures located within edge cells of the SRAM cell array, and further connected to chip bond pads located on wafer back-side, such that IR drop can be reduced. The back-side chip bumping scheme can save one-time protection layer formation on the wafer front-side, which in turn allows for reducing the process cost.

In other words, some of the conductive features (e.g., butt contact, word-line) can be moved from the wafer front-side to the wafer back-side to achieve a capability for cell scaling down and RC reduction. For example, the butt contacts 258d and 258g can be disposed on wafer back-side to connect the source/drain region and the gate electrode layer. The back-side butt contacts 258d and 258g can be fabricated simultaneously with back-side via in a same process, and thus fabrication of the back-side butt contacts 258d and 258g will not result in additional processes and hence additional cost and without additional metal materials and masks. Moreover, the word-lines B-M1-WL, B-M2-WL can be disposed in different metal levels M1, M2 on wafer back-side to have a wider width thereof, such that IR drop of the semiconductor structure can be reduced. Further, a metal pitch of word-lines B-M1-WL, B-M2-WL can also be enlarged, such that the word-lines B-M1-WL, B-M2-WL with enlarging metal line pitch can be formed by a single lithography patterning, which in turn reduces the manufacturing cost. In some embodiments, the word-line B-M1-WL can be interchangeably referred to a word-line landing pad or a word-line landing line.

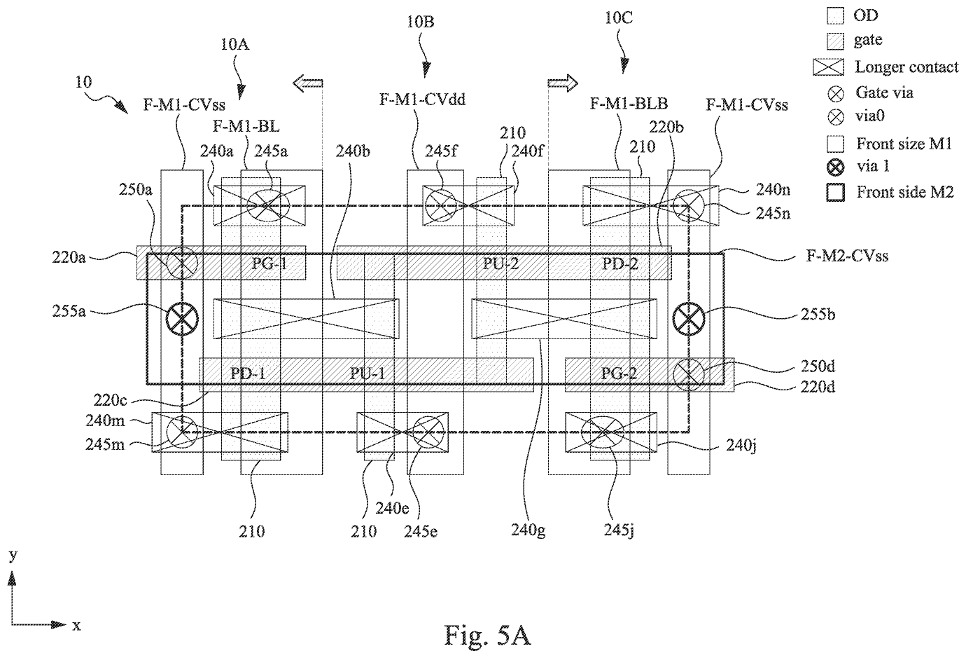

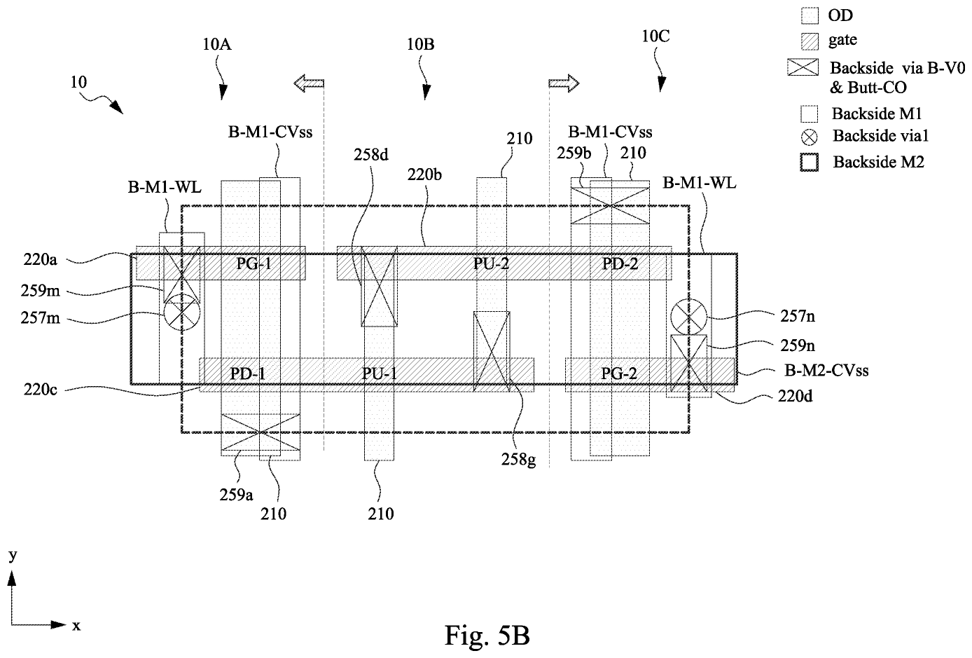

Reference is made to FIGS. 5A and 5B. FIGS. 5A and 5B illustrate a SRAM cell layout diagram of a circuit on a front-side and a back-side of a semiconductor structure, respectively, according to some embodiments of the present disclosure. While FIGS. 5A and 5B show an embodiment of the semiconductor structure with a different metal line routing method than the semiconductor structure in FIGS. 2A-3F. In addition, the present disclosure may repeat reference numerals and/or letters in the various examples. This repetition is for the purpose of simplicity and clarity and does not in itself dictate a relationship between the various embodiments and/or configurations discussed.

As shown in FIGS. 5A and 5B, the front-side M1 level may include bit-line F-M1-BL, bit-line-bar F-M1-BLB, and power supply voltage lines F-M1-CVdd, F-M1-CVss. On the other hands, the front-side M1 level may be free of word-line. Therefore, the bit-line F-M1-BL and bit-line-bar F-M1-BLB can be disposed in a lower metal layer to lower the resistance and the capacitance of the SRAM cell, such that the speed of SRAM cell can be improved. In some embodiments, the front-side M2 level may include a power supply voltage line CVss. In addition, the power supply voltage lines CVdd, CVss located on front-side are connected to power supply voltage lines CVdd, CVss located on back-side through tapping structures located within edge cells of the SRAM cell array, and further connected to chip bond pads located on wafer back-side, such that IR drop can be reduced. The back-side chip bumping scheme can save one-time protection layer formation on the wafer front-side, which in turn allows for reducing the process cost.

In other words, some of the conductive features (e.g., butt contact, power supply voltage line CVss, word-line) can be moved from the wafer front-side to the wafer back-side to achieve a capability for cell scaling down and RC reduction. For example, the front-side M1 level may include butt contacts 258d and 258g disposed on wafer back-side to connect the source/drain region and the gate electrode layer. The back-side butt contacts 258d and 258g can be fabricated simultaneously with back-side via in a same process, and thus fabrication of the back-side butt contacts 258d and 258g will not result in additional processes and hence additional cost and without additional metal materials and masks. Moreover, the back-side M1 level may include the power supply voltage line B-M1-CVss and word-line B-M1-WL to have a wider width thereof, such that IR drop of the semiconductor structure can be reduced. Further, a metal pitch of power supply voltage lines B-M1-CVss and word-line B-M1-WL can also be enlarged, such that the back-side power supply voltage line B-M1-CVss and word-line B-M1-WL with enlarging metal line pitch can be formed by a single lithography patterning, which in turn reduces the manufacturing cost. Furthermore, the back-side M2 level may include word-line B-M2-WL to have a wider width, such that IR drop of the semiconductor structure can be further reduced.

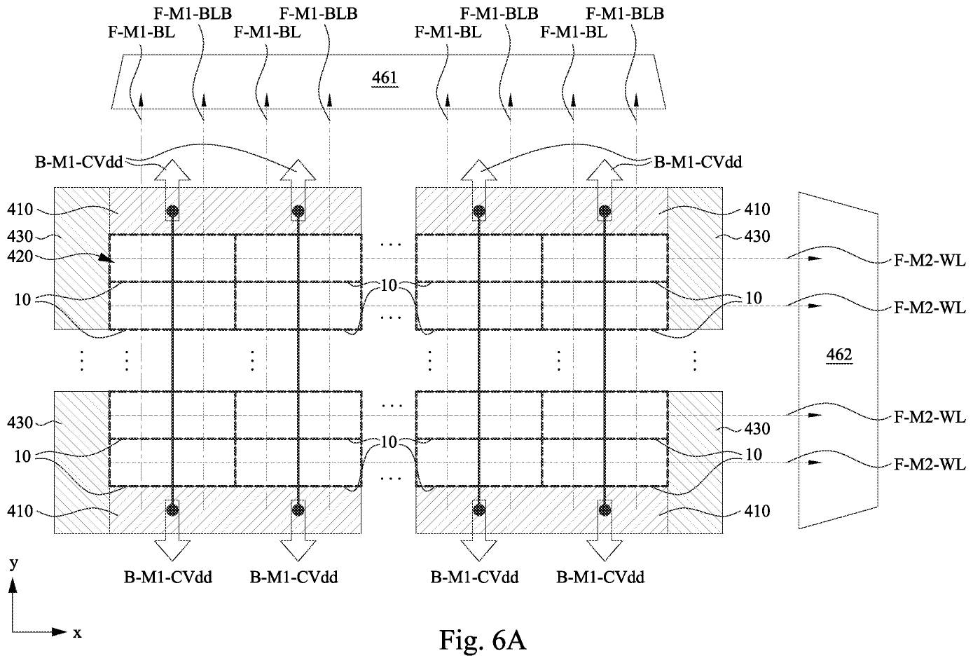

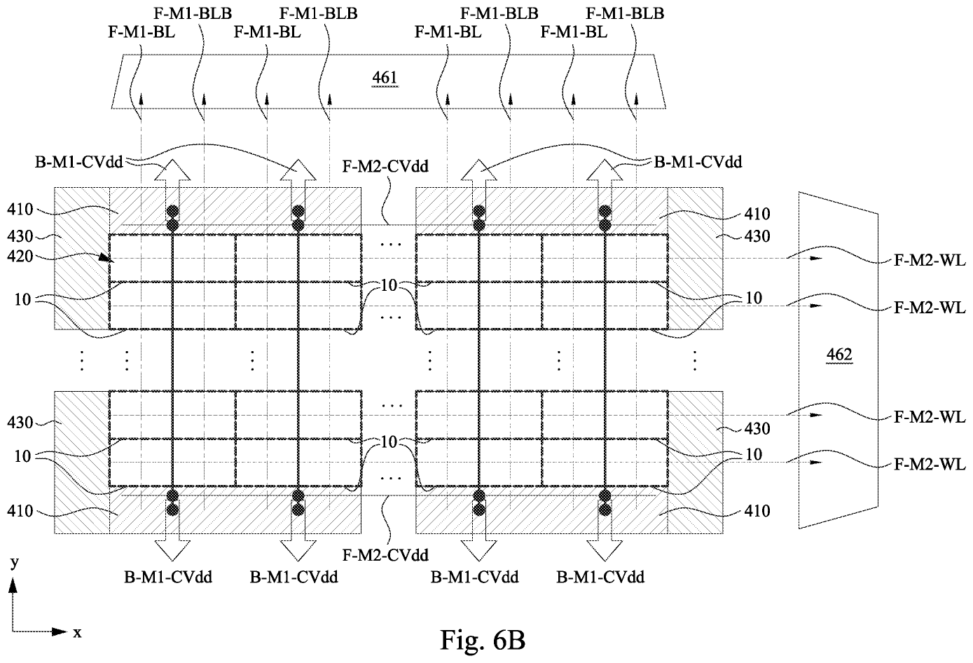

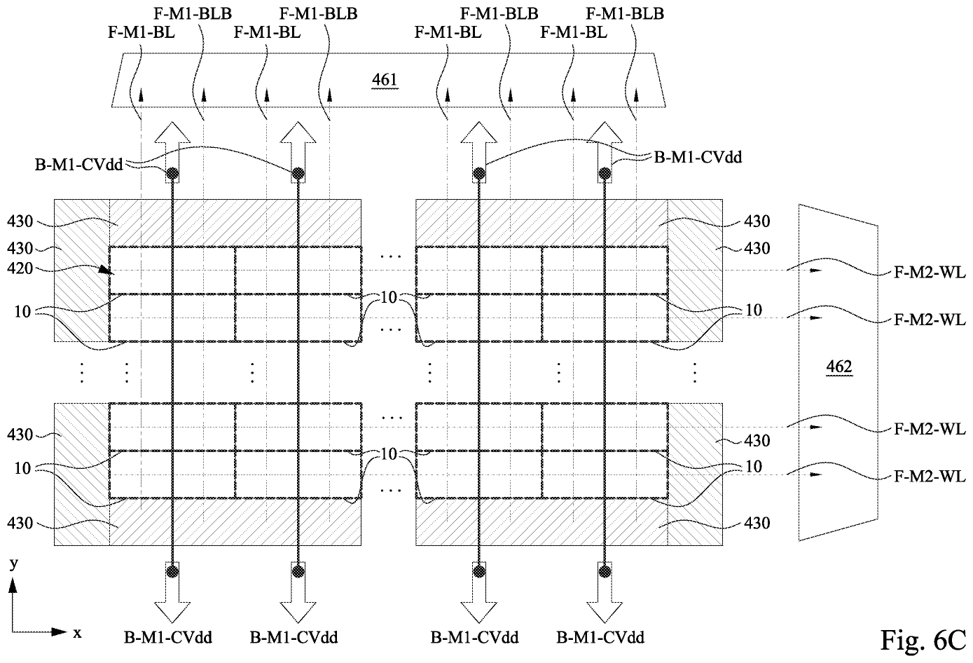

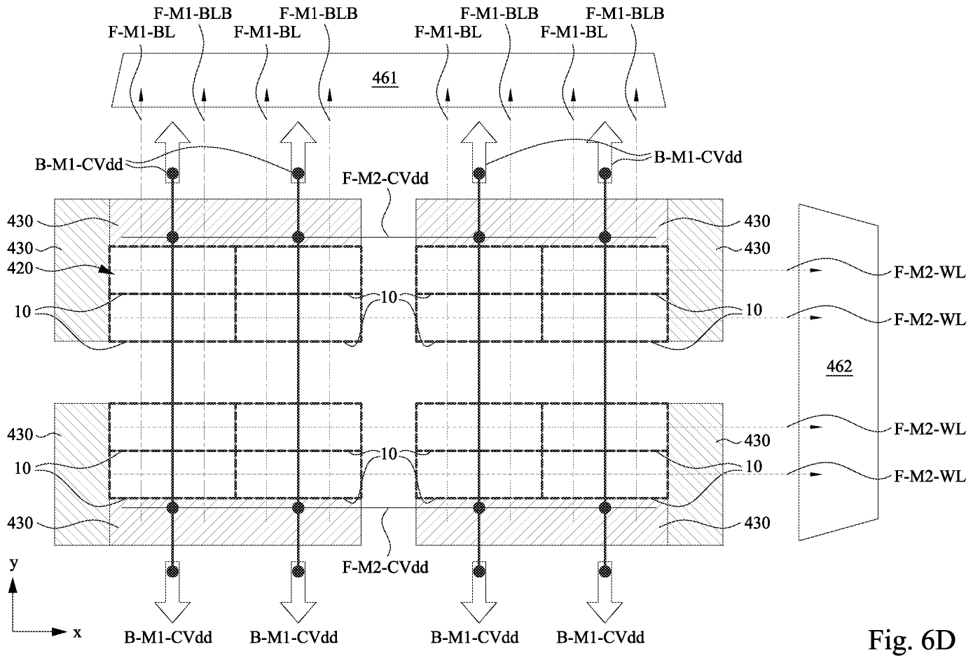

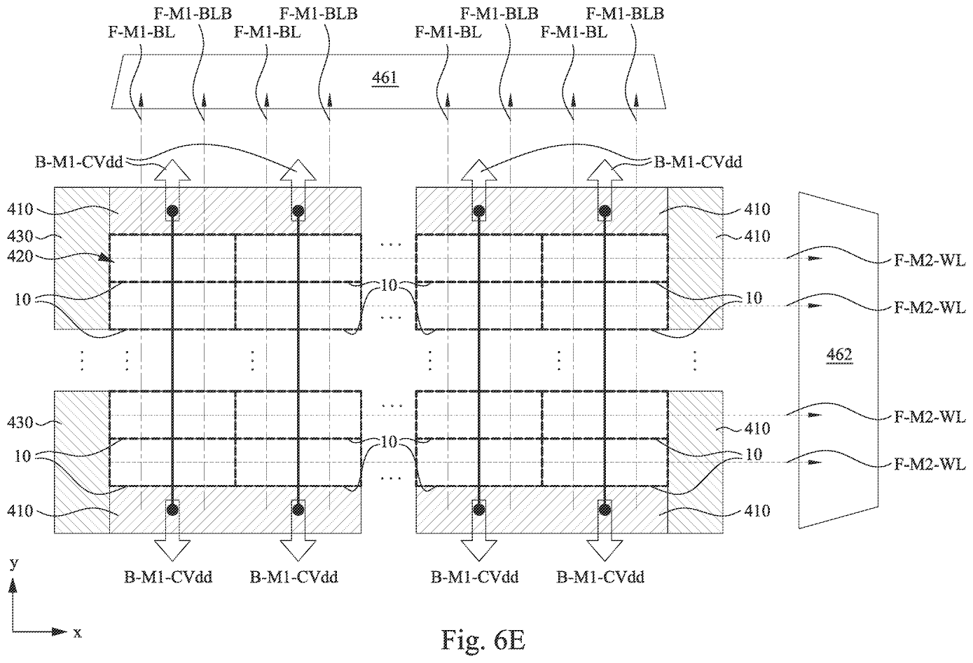

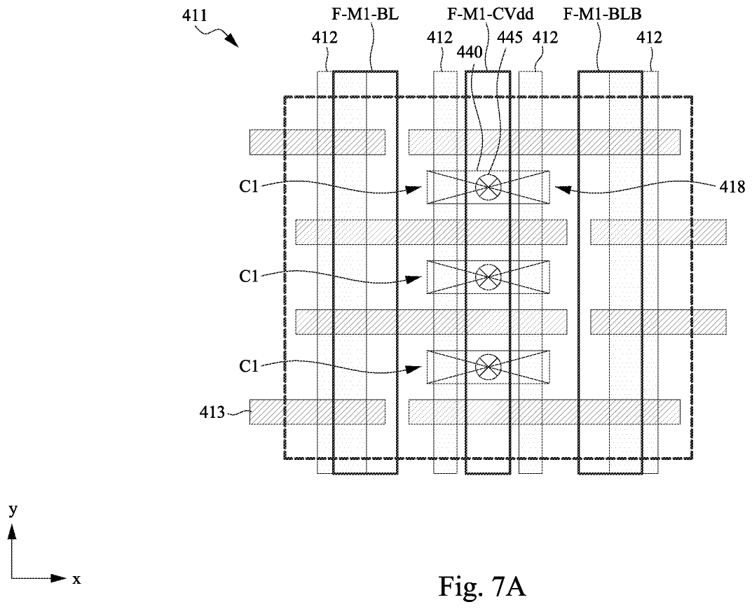

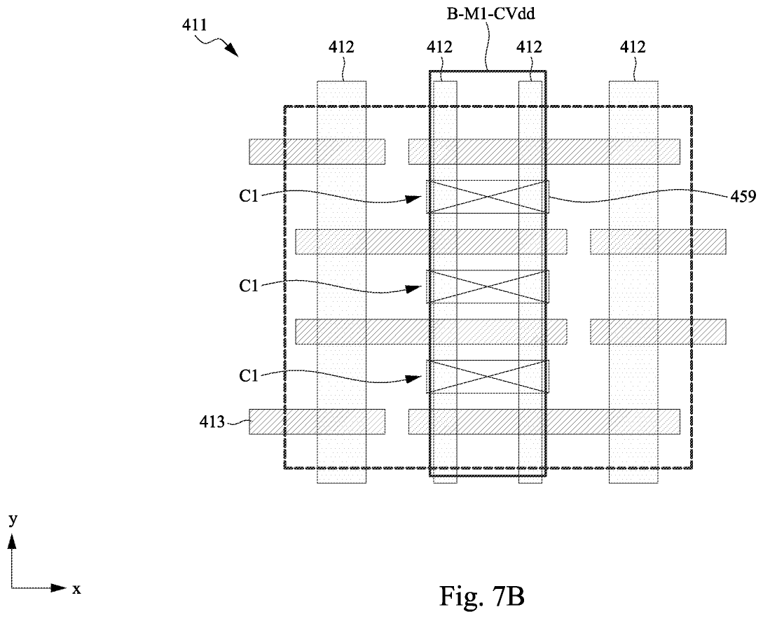

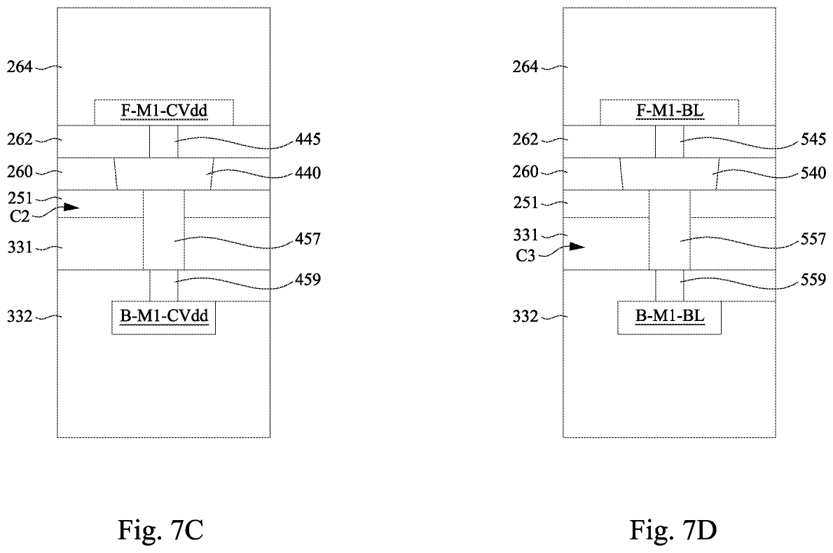

Reference is made to FIGS. 6A-7D. FIGS. 6A-6E are top views of a SRAM cell array according to embodiments of the present disclosure. FIGS. 7A and 7B illustrate enlarged views of an edge tap regions 410 in FIG. 6A and including CVdd tap structures on a front-side and a back-side of a semiconductor structure, respectively, according to embodiments of the present disclosure. FIGS. 7C and 7D illustrate cross-sectional views of a CVdd tap structure and a bit-line tap structure according to embodiments of the present disclosure.

As shown in FIG. 6A, the SRAM cell array may include, SRAM cell region 420 including SRAM cell units 10 or arrays of the SRAM cell units 10 extending in a column direction (i.e., Y direction), edge tap regions 410 each including edge tap cells, edge cell regions 430 each including edge cells, and peripheral circuits including a Y-multiplexer (MUX), writer driver, and sense amplifier 461, and a word-line driver/selector 462. The SRAM cell region 420 is disposed in the column direction between the edge tap regions 410. On the other hands, the SRAM cell region 420 is disposed in the row direction (i.e., X direction) perpendicular to the column direction between the edge cell regions 430. In some embodiments, the SRAM cell units 10 can be interchangeably referred to bitcells. Although one Y-MUX, writer driver, and sense amplifier 461 is illustrated in FIG. 6A, the SRAM cell array can include another Y-MUX and sense amplifier disposed on another side of the SRAM cell region 420 and the edge tap regions 410 opposite to the Y-MUX, writer driver, and sense amplifier 461. Although one word-line driver/selector 462 is illustrated in FIG. 6A, the SRAM cell array can include another word-line driver/selector disposed on another side of the SRAM cell region 420 and the edge tap regions 110 opposite to the word-line driver/selector 462.

The bit-lines F-M1-BL and the bit-line-bars F-M1-BLB that carry signals complemental to those carried by the bit-lines F-M1-BL extend along the column direction and are electrically connected to the SRAM cell units 10 and the Y-MUX, writer driver, and sense amplifier 461. The word-lines F-M2-WL extend over the SRAM cell units 10 in the SRAM cell region 420 along the row direction and are electrically connected to the SRAM cell units 10 and the wordline driver/selector 163. The Y-MUX, writer driver, and sense amplifier 461 and the word-line driver/selector 462 are operative to select SRAM cell units 10 such that data stored in the SRAM cell units 10 can be read and output by the Y-MUX, writer driver, and sense amplifier 461, and new data can be written to the SRAM cell units 10. In some embodiments, the power supply voltage lines F-M1-CVdd, B-M1-CVss, B-M2-CVss extend along the column direction, and are connected to source regions of corresponding transistors of the SRAM cell units 10 in the column direction. When terminal voltages provided by, for example, a power supply source, are applied to the power supply voltage lines F-M1-CVdd, B-M1-CVss, B-M2-CVss, respectively, the SRAM cell units 10 connected to the power supply voltage lines F-M1-CVdd, B-M1-CVss, B-M2-CVss are energized to allow the SRAM cell units 10 to operate, such that the data stored thereof can be read therefrom or new data can be written thereto by operation of the Y-MUX, writer driver, and sense amplifier 461 and the word-line driver/selector 462.

In some embodiments, the edge tap regions 410 are above and below the uppermost and lowermost boundaries of the SRAM cell region 420, respectively, from the top view. In greater detail, the upper one of the edge tap regions 410 is disposed between the Y-MUX, writer driver, and sense amplifier 461 and the uppermost boundary of the SRAM cell region 420 in the column direction. The edge tap cells 411 (see FIGS. 7A and 7B) are formed in the edge tap regions 410. The edge tap cells 411 are used for connecting the power supply voltage line F-M1-CVdd (see FIG. 7A) on the wafer front-side to the power supply voltage line B-M1-CVdd (see FIG. 7B) on the wafer back-side through connection paths C1 (see FIGS. 7A and 7B) formed therein. In some embodiments, the edge tap cells 411 do not store data as the SRAM cell units 10 in the SRAM cell region 420 (see FIG. 6A) but instead provide connections between the front-side and back-side power supply voltage lines, and thus the edge tap cells 411 can be interchangeably referred to edge dummy cells.

As shown in FIGS. 7A and 7B, an outer boundary the edge tap cell 411 is illustrated using a dashed line. The edge tap cells 411 may include semiconductor sheets 412. The semiconductor sheets 412 are stacked along the Z-direction (not shown) and are wrapped by the corresponding dummy gate electrode layers 413. In some embodiments, semiconductor sheets 412 each has a length extending along Y-direction from the top view. The edge tap cells 411 include dummy gate electrode layers 413 extending in the X-direction and across the corresponding semiconductor sheets 412. Source/drain regions 418 are between corresponding adjacent two of the dummy gate electrode layers 413. In some embodiments, the source/drain regions 418 may be P-type source/drain regions. In some embodiments, the source/drain regions 418 may be N-type source/drain regions. In some embodiments, the dummy gate electrode layers 413 can be interchangeably referred to dummy gate patterns, dummy gate strips, dummy gate electrodes, dummy gate layers, or dummy gates. In some embodiments, the source/drain regions 418 can be interchangeably referred to dummy source/drain patterns or dummy epitaxial structures.

The front-side power supply voltage line F-M1-CVdd (see FIG. 7A) is connected to the back-side power supply voltage line B-M1-CVdd (see FIG. 7B) through the connection path C1 including a front-side source/drain via 445 (see FIG. 7A), a front-side source/drain contact 440 (see FIG. 7A), the source/drain region 418, a back-side conductive via 459 (see FIG. 7B). In some embodiments, the source/drain region 418 can be interchangeably referred to a CVdd tap structure. In greater detail, as shown in FIG. 7A, metal lines disposed at the M1 level on the front-side of the edge tap cell 411 may include the power supply voltage lines F-M1-CVdd, the bit-line F-M1-BL, the bit-line-bar F-M1-BLB. The metal lines disposed at the M1 level on the front-side of the edge tap cell 411 may have lengthwise directions parallel to the Y-direction (e.g., column direction). Accordingly, each of these metal lines disposed at the M1 level on the front-side of the edge tap cell 411 may extend into, and may be connected to, a plurality of SRAM cell units 10 in the same column. As shown in FIG. 7B metal lines disposed at the M1 level on the back-side of the edge tap cell 411 may include the back-side power supply voltage line B-M1-CVdd. The metal lines disposed at the M1 level on the back-side of the edge tap cell 411 may have lengthwise directions parallel to the Y-direction (e.g., column direction). In some embodiments, each of these metal lines disposed at the M1 level on the back-side of the edge tap cell 411 may not extend into, and may not be connected to, a plurality of SRAM cell units 10. In some embodiments, each of these metal lines disposed at the M1 level on the back-side of the edge tap cell 411 may extend into, and may be connected to, a plurality of SRAM cell units 10 in the same column.

In some embodiments, as shown in FIG. 7C, the front-side power supply voltage line F-M1-CVdd is connected to the back-side power supply voltage line B-M1-CVdd through a connection path C2. The structure and function of the components and their relationships in the connection path C2 are substantially the same as the connection path C1 shown in FIGS. 7A and 7B, and the related detailed descriptions may refer to the foregoing paragraphs, and are not described again herein. It is noted that, the difference between the present embodiment and the embodiment in FIGS. 7A and 7B is in that the connection path C2 includes the front-side via 445, the front-side contact 440, a tap via 457, and the back-side conductive via 459. In some embodiments, the tap via 457 can be interchangeably referred to a CVdd tap structure. In FIG. 7C, the front-side via 445 and the front-side contact 440 can be formed in the ILD layers 262 and 260, the tap via 457 can have a top portion formed in the STI structure 251 and a lower portion formed in the back-side dielectric 331, and the back-side conductive via 459 can be formed in the IMD layer 332.

Reference is made to FIG. 6A. The edge cell regions 430 are formed, on the left and right sides of a combined region including the edge tap regions 410 and the SRAM cell region 420. As such, the edge tap regions 410 and the edge cell regions 430 completely surround the SRAM cell region 420. In some embodiments, the edge cell regions 430 do not store data as the SRAM cell units 10 in the SRAM cell region 420, and thus the edge cells in the edge cell regions 430 can be interchangeably referred to edge dummy cells. In some embodiments, the edge cells in the right one of the edge cell regions 430 can be edge tap cells. As shown in FIG. 7D, the front-side bit-lines F-M1-BL can be connected to the back-side bit-lines B-M1-BL (see FIG. 7B) through a connection path C3. The structure and function of a front-side via 545, a front-side contact 540, a tap via 557, and a back-side conductive via 559 and their relationships in the connection path C3 are substantially the same as those of the front-side via 445, the front-side contact 440, the tap via 457, and the back-side conductive via 459 in the connection path C2 shown in FIG. 7C, and the related detailed descriptions may refer to the foregoing paragraphs, and are not described again herein.

Reference is made to FIG. 6B. The structure and function of the components and their relationships in the semiconductor structure are substantially the same as the semiconductor structure shown in FIG. 6A, and the related detailed descriptions may refer to the foregoing paragraphs, and are not described again herein. It is noted that, the difference between the present embodiment and the embodiment in FIG. 6A is in that the SRAM cell array in FIG. 6B further includes power supply voltage mesh lines F-M2-CVdd disposed at the M2 level on the wafer front-side. The power supply voltage mesh lines F-M2-CVdd are located at array edge cells (e.g., the edge tap regions 410) and extend along the X-direction (e.g., row direction). The power supply voltage mesh lines F-M2-CVdd are electrically connected to the plurality of power supply voltage mesh lines F-M1-CVdd extending along the Y-direction (e.g., column direction).

Reference is made to FIG. 6C. The structure and function of the components and their relationships in the semiconductor structure are substantially the same as the semiconductor structure shown in FIG. 6A, and the related detailed descriptions may refer to the foregoing paragraphs, and are not described again herein. It is noted that, the difference between the present embodiment and the embodiment in FIG. 6A is in that the edge tap regions 410 are replaced with edge cell regions 430, and the connection paths C1 are located at regions outside of the SRAM cell array.

Reference is made to FIG. 6D. The structure and function of the components and their relationships in the semiconductor structure are substantially the same as the semiconductor structure shown in FIG. 6A, and the related detailed descriptions may refer to the foregoing paragraphs, and are not described again herein. It is noted that, the difference between the present embodiment and the embodiment in FIG. 6A is in that the edge tap regions 410 are replaced with edge cell regions 430, and the connection paths C1 are located at regions outside of the SRAM cell array. The SRAM cell array in FIG. 6D further includes power supply voltage mesh lines F-M2-CVdd disposed at the M2 level on the wafer front-side. The power supply voltage mesh lines F-M2-CVdd are located at array edge cells (e.g., edge cell regions 430) and extend along the X-direction (e.g., row direction). The power supply voltage mesh lines F-M2-CVdd are electrically connected to the plurality of power supply voltage mesh lines F-M1-CVdd extending along the Y-direction (e.g., column direction).

Reference is made to FIG. 6E. The structure and function of the components and their relationships in the semiconductor structure are substantially the same as the semiconductor structure shown in FIG. 6A, and the related detailed descriptions may refer to the foregoing paragraphs, and are not described again herein. It is noted that, the difference between the present embodiment and the embodiment in FIG. 6A is in that one of the edge cell regions 430 between the word-line driver/selector 462 and the SRAM cell region 420 can be replaced with an edge tap region 410.

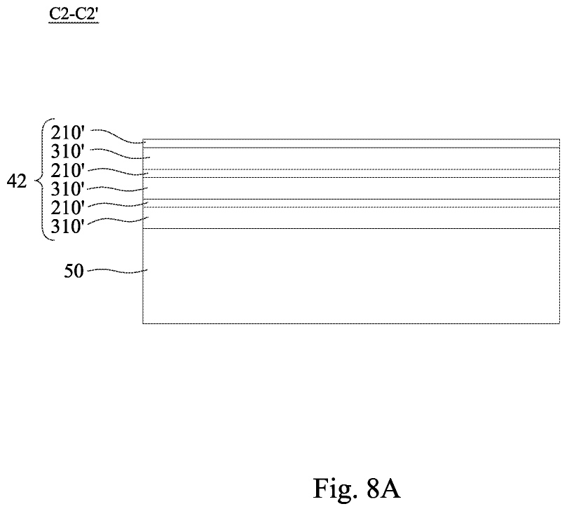

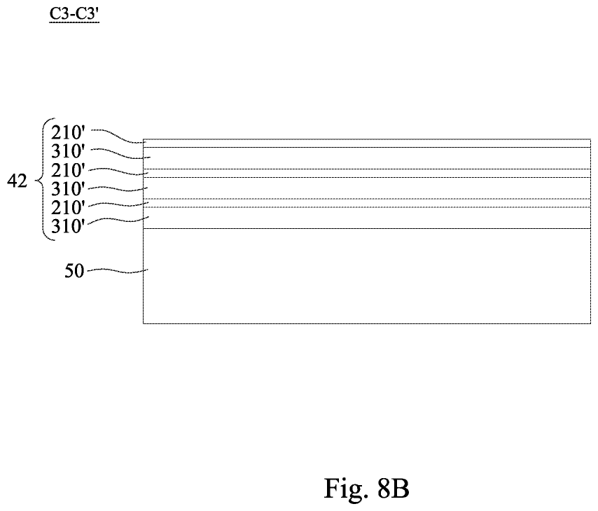

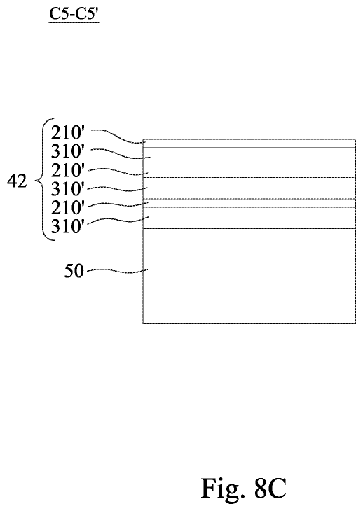

Reference is made to FIGS. 8A to 23C. FIGS. 8A to 23C illustrate the cross-sectional views of intermediate stages in the formation of a semiconductor structure in accordance with some embodiments. FIGS. 8A, 9A, 10A, 11A, 12A, 13A, 14A, 15A, 16A, 17A, 18A, 19A, 20A, 21A, 22A, and 23A illustrate cross-sectional views obtained from the reference cross-section C2-C2′ in FIGS. 2A and 2B of intermediate stages in the formation of a semiconductor structure in accordance with some embodiments. FIGS. 8B, 9B, 10B, 11B, 12B, 13B, 14B, 15B, 16B, 17B, 18B, 19B, 20B, 21B, 22B, and 23B illustrate cross-sectional views obtained from the reference cross-section C3-C3′ in FIGS. 2A and 2B of intermediate stages in the formation of a semiconductor structure in accordance with some embodiments. FIGS. 8C, 9C, 10C, 11C, 12C, 13C, 14C, 15C, 16C, 17C, 18C, 19C, 20C, 21C, 22C, and 23C illustrate cross-sectional views obtained from the reference cross-section C5-C5′ in FIGS. 2A and 2B of intermediate stages in the formation of a semiconductor structure in accordance with some embodiments.

Reference is made to FIGS. 8A, 8B, and 8C. A substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

Subsequently, a multi-layer stack 42 is formed over the substrate 50. The multi-layer stack 42 includes alternating first semiconductor layers 310′ and second semiconductor layers 210′. The first semiconductor layers 310′ formed of a first semiconductor material, and the second semiconductor layers 210′ are formed of a second semiconductor material. The semiconductor materials may each be selected from the candidate semiconductor materials of the substrate 50. In some embodiments, the multi-layer stack 42 includes three layers of each of the first semiconductor layers 310′ and the second semiconductor layers 210′. It should be appreciated that the multi-layer stack 42 may include any number of the first semiconductor layers 310′ and the second semiconductor layers 210′.

In some embodiments, and as will be subsequently described in greater detail, the first semiconductor layers 310′ will be removed and the second semiconductor layers 210′ will patterned to form channel regions for the nano-FETs. The first semiconductor layers 310′ are sacrificial layers (or dummy layers), which will be removed in subsequent processing to expose the top surfaces and the bottom surfaces of the second semiconductor layers 210′. The first semiconductor material of the first semiconductor layers 310′ is a material that has a high etching selectivity from the etching of the second semiconductor layers 210′, such as silicon germanium. The second semiconductor material of the second semiconductor layers 210′ is a material suitable for both n-type and p-type devices, such as silicon.

In some embodiments, the first semiconductor material of the first semiconductor layers 310′ may be made of a material, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 210′ may be made of a material, such as silicon, silicon carbide, a III-V compound semiconductor, a II-VI compound semiconductor, or the like. The first semiconductor material and the second semiconductor material may have a high etching selectivity from the etching of one another. Each of the layers of the multi-layer stack 42 may be grown by a process such as vapor phase epitaxy (VPE) or molecular beam epitaxy (MBE), deposited by a process such as chemical vapor deposition (CVD) or atomic layer deposition (ALD), or the like. In some embodiments, the multi-layer stack 42 may have a thickness in a range from about 70 to 120 nm, such as about 70, 80, 90, 100, 110, or 120 nm. In some embodiments, each of the layers may have a small thickness, such as a thickness in a range of about 5 nm to about 40 nm. In some embodiments, some layers (e.g., the second semiconductor layers 210′) are formed to be thinner than other layers (e.g., the first semiconductor layers 310′). For example, in embodiments in which the first semiconductor layers 310′ are sacrificial layers (or dummy layers) and the second semiconductor layers 210′ are patterned to form channel regions for the nano-FETs.

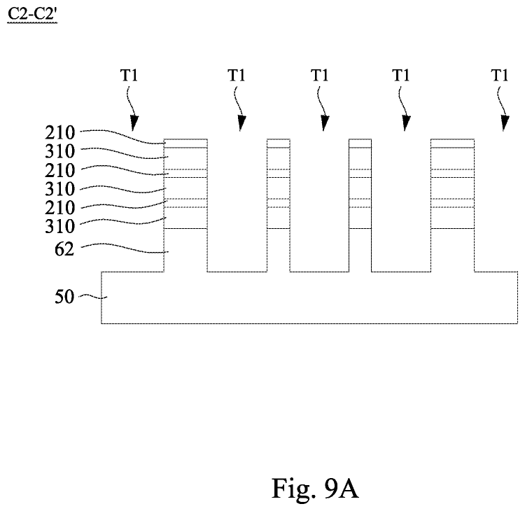

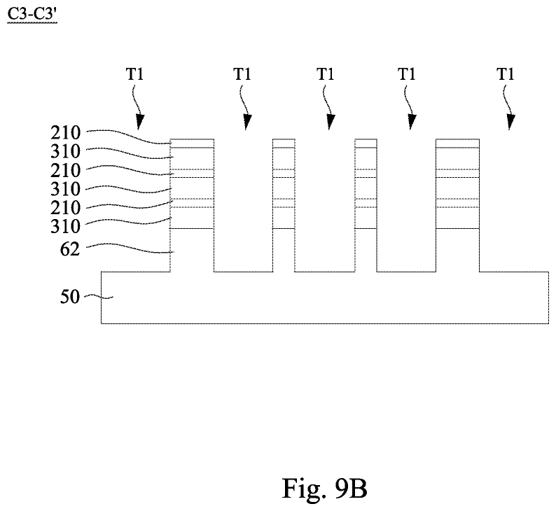

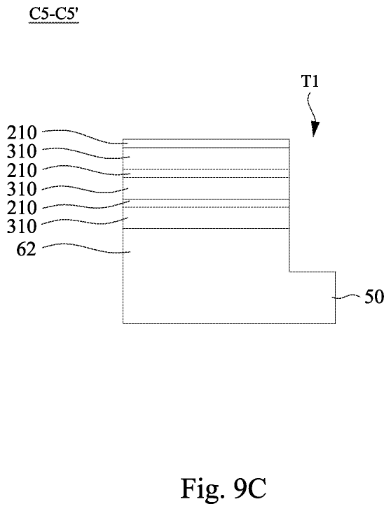

Reference is made to FIGS. 9A, 9B, and 9C. Trenches T1 are patterned in the substrate 50 and the multi-layer stack 42 to form fins 62, first semiconductor sheets 310, and second semiconductor sheets 210. The fins 62 are semiconductor strips patterned in the substrate 50. The first semiconductor sheets 310 and the second semiconductor sheets 210 include the remaining portions of the first semiconductor layers 310′ and the second semiconductor layers 210′, respectively. The trenches T1 may be patterned by any acceptable etch process, such as a reactive ion etch (RIE), neutral beam etch (NBE), the like, or a combination thereof. The etching may be anisotropic.

The fins 62 and the first and second semiconductor sheets 310, 210 may be patterned by any suitable method. For example, the fins 62 and the first and second semiconductor sheets 310, 210 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as masks to pattern the fins 62 and the first and second semiconductor sheets 310, 210. In some embodiments, the mask (or other layer) may remain on the first and second semiconductor sheets 310, 210. The fins 62 and the first and second semiconductor sheets 310, 210 may each have widths in a range of about 8 nm to about 40 nm. In some embodiments, the fins 62 and the first and second semiconductor sheets 310, 210 have substantially equal widths.

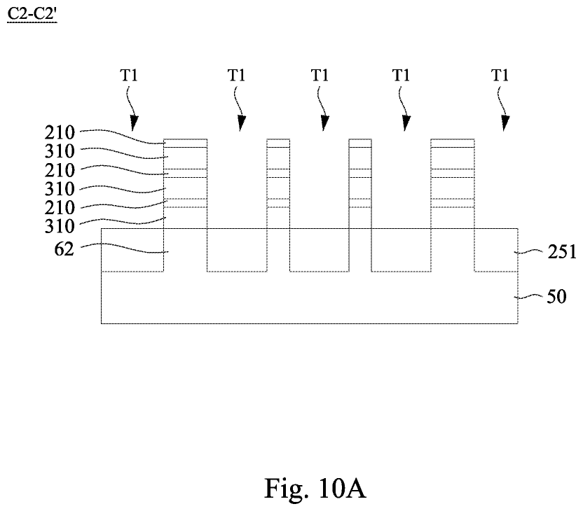

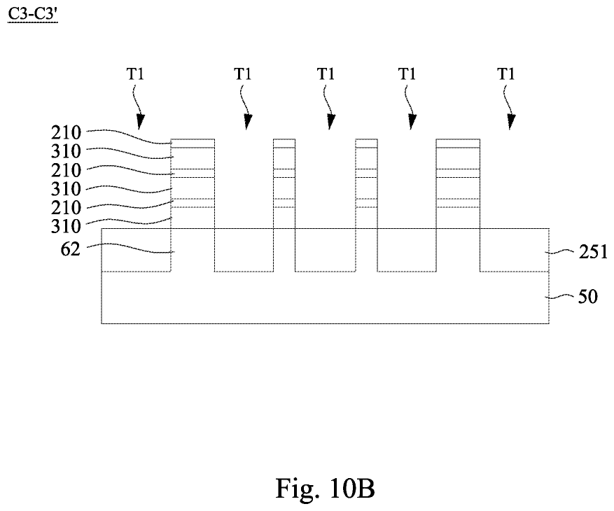

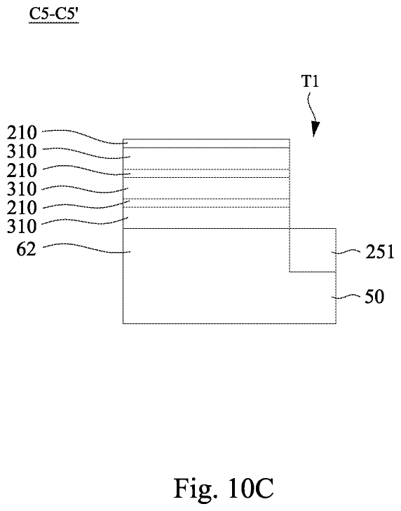

Reference is made to FIGS. 10A, 10B, and 10C. STI structures 251 are formed over the substrate 50 and between adjacent fins 62. The STI structures 251 are disposed around at least a portion of the fins 62 such that at least a portion of the first and second semiconductor sheets 310, 210 protrude from between adjacent STI structures 251. In some embodiments, the top surfaces of the STI structures 251 are coplanar (within process variations) with the top surfaces of the fins 62. In some embodiments, the top surfaces of the STI structures 251 are above or below the top surfaces of the fins 62. The STI structures 251 separate the features of adjacent devices.

The STI structures 251 may be formed by any suitable method. For example, an insulation material can be formed over the substrate 50 and the first and second semiconductor sheets 310, 210, and between adjacent fins 62. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the first and second semiconductor sheets 310, 210. Although the STI structures 251 are each illustrated as a single layer, some embodiments may utilize multiple layers. For example, in some embodiments a liner (not separately illustrated) may first be formed along surfaces of the substrate 50, the fins 62, and the first and second semiconductor sheets 310, 210. Thereafter, a fill material, such as those previously described may be formed over the liner.

A removal process is then applied to the insulation material to remove excess insulation material over the first and second semiconductor sheets 310, 210. In some embodiments, a planarization process such as a chemical mechanical polish (CMP), an etch-back process, combinations thereof, or the like may be utilized. In embodiments in which a mask remains on the first and second semiconductor sheets 310, 210, the planarization process may expose the mask or remove the mask. After the planarization process, the top surfaces of the insulation material and the mask (if present) or the first and second semiconductor sheets 310, 210 are coplanar (within process variations).

Accordingly, the top surfaces of the mask (if present) or the first and second semiconductor sheets 310, 210 are exposed through the insulation material. In some embodiments, no mask remains on the first and second semiconductor sheets 310, 210. The insulation material is then recessed to form the STI structures 251. The insulation material is recessed, such as in a range from about 30 nm to about 80 nm, such that at least a portion of the first and second semiconductor sheets 310, 210 protrude from between adjacent portions of the insulation material. Further, the top surfaces of the STI structures 251 may have a flat surface as illustrated, a convex surface, a concave surface (such as dishing), or a combination thereof. The top surfaces of the STI structures 251 may be formed flat, convex, and/or concave by an appropriate etch. The insulation material may be recessed using any acceptable etching process, such as one that is selective to the material of the insulation material (e.g., selectively etches the insulation material of the STI structures 251 at a faster rate than the materials of the fins 62 and the first and second semiconductor sheets 310, 210). For example, an oxide removal may be performed using dilute hydrofluoric (dHF) acid.

The process previously described is just one example of how the fins 62 and the first and second semiconductor sheets 310, 210 may be formed. In some embodiments, the fins 62 and/or the first and second semiconductor sheets 310, 210 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the first and second semiconductor sheets 310, 210. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

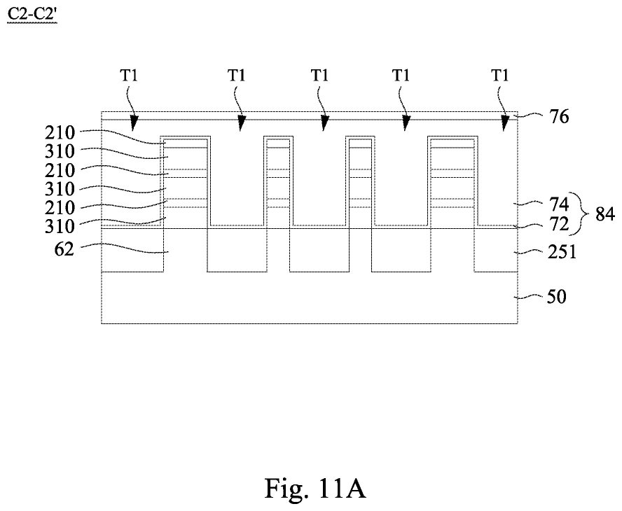

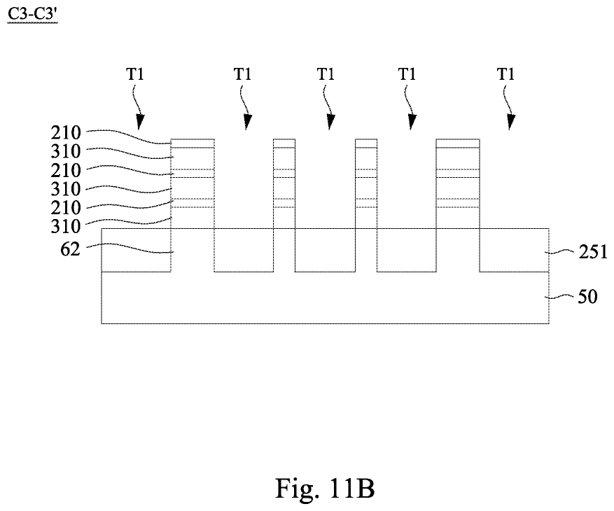

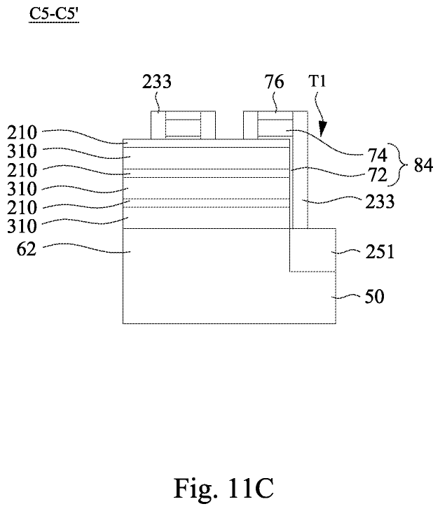

Reference is made to FIGS. 11A, 11B, and 11C. A dummy dielectric layer, a dummy gate layer, and a mask layer are sequentially formed on the fins 62 and the first and second semiconductor sheets 310, 210. The dummy dielectric layer is formed on the fins 62 and the first and second semiconductor sheets 310, 210. The dummy dielectric layer may be formed of a dielectric material such as silicon oxide, silicon nitride, a combination thereof, or the like, which may be deposited or thermally grown according to acceptable techniques. Subsequently, a dummy gate layer is formed over the dummy dielectric layer. Subsequently, a mask layer is formed over the dummy gate layer. The dummy gate layer may be deposited over the dummy dielectric layer and then planarized, such as by a CMP. The mask layer may be deposited over the dummy gate layer. The dummy gate layer may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer may be formed of material(s) that have a high etching selectivity from the etching of insulation materials, e.g., the STI structures 251 and/or the dummy dielectric layer. The mask layer may be formed of a dielectric material such as silicon nitride, silicon oxynitride, or the like. In some embodiments, the dummy dielectric layer covers the fins 62, the first and second semiconductor sheets 310, 210, and the STI structures 251, such that the dummy dielectric layer extends over the STI structures 251 and between the dummy gate layer and the STI structures 251. In another embodiment, the dummy dielectric layer covers only the fins 62 and the first and second semiconductor sheets 310, 210.

The mask layer is patterned using acceptable photolithography and etching techniques to form masks 76. The pattern of the masks 76 is then transferred to the dummy gate layer by any acceptable etching technique to form dummy gates 74. The pattern of the masks 76 may optionally be further transferred to the dummy dielectric layer by any acceptable etching technique to form dummy dielectrics 72. The dummy gate 74 and the dummy dielectric 72 may be collectively referred to as a dummy gate structure 84. The dummy gate structures 84 cover portions of the first and second semiconductor sheets 310, 210 that will be exposed in subsequent processing to form channel regions. Specifically, the dummy gate structures 84 extend along the portions of the second semiconductor sheets 210 that will be patterned to form channel regions. The pattern of the masks 76 may be used to physically separate adjacent dummy gate structures 84. The dummy gate structures 84 may also have lengthwise directions substantially perpendicular (within process variations) to the lengthwise directions of the fins 62. The masks 76 can optionally be removed after patterning, such as by any acceptable etching technique.

Gate spacers 233 are formed over the first and second semiconductor sheets 310, 210, on exposed sidewalls of the masks 76, the dummy gates 74, and the dummy dielectrics 72. In some embodiments, the gate spacers 233 can be interchangeably referred to top spacers or upper gate spacers. In some embodiments, the gate spacers 233 may have a lateral dimension in a range from about 4 nm to about 12 nm. In some embodiments, the gate spacer 233 may include multiple dielectric material and selected from a group consist of SiO₂, Si₃N₄, carbon doped oxide, nitrogen doped oxide, porous oxide, air gap, or combinations thereof. The gate spacers 233 may be formed by conformally depositing one or more dielectric material(s) and subsequently etching the dielectric material(s). Acceptable dielectric materials may include silicon oxide, silicon nitride, silicon oxynitride, silicon oxycarbonitride, or the like, which may be formed by a conformal deposition process such as chemical vapor deposition (CVD), plasma-enhanced chemical vapor deposition (PECVD), atomic layer deposition (ALD), plasma-enhanced atomic layer deposition (PEALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gate structures 84 (thus forming the gate spacers 233).

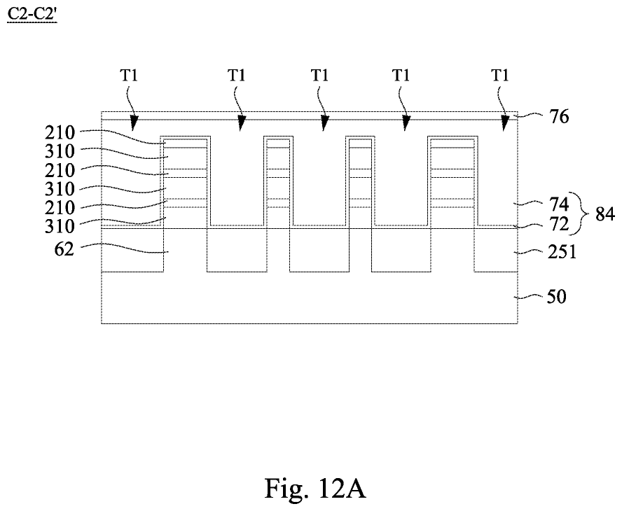

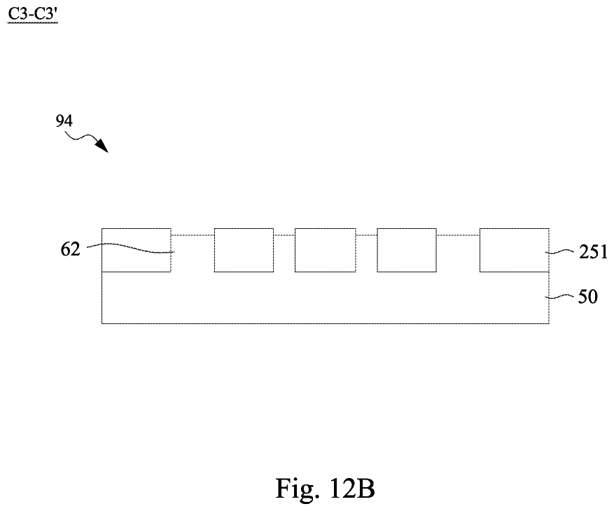

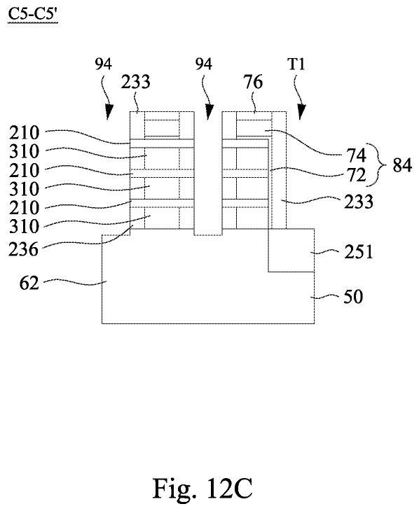

Reference is made to FIGS. 12A, 12B, and 12C. Source/drain recesses 94 are formed in the first and second semiconductor sheets 310, 210. In some embodiments, the source/drain recesses 94 extend through the first and second semiconductor sheets 310, 210 and into the fins 62. In some embodiments, the fins 62 may be etched such that bottom surfaces of the source/drain recesses 94 are disposed below the top surfaces of the STI structures 251. The source/drain recesses 94 may be formed by etching the first and second semiconductor sheets 310, 210 using an anisotropic etching process, such as a RIE, a NBE, or the like. The gate spacers 233 and the dummy gate structures 84 collectively mask portions of the fins 62 and/or the first and second semiconductor sheets 310, 210 during the etching processes used to form the source/drain recesses 94. A single etch process may be used to etch each of the first and second semiconductor sheets 310, 210, or multiple etch processes may be used to etch the first and second semiconductor sheets 310, 210. Timed etch processes may be used to stop the etching of the source/drain recesses 94 after the source/drain recesses 94 reach a desired depth.

Subsequently, inner spacers 236 are formed on sidewalls of the remaining portions of the first semiconductor sheets 310, e.g., those sidewalls exposed by the source/drain recesses 94. As will be subsequently described in greater detail, source/drain regions will be subsequently formed in the source/drain recesses 94, and the first semiconductor sheets 310 will be subsequently replaced with corresponding gate structures. The inner spacers 236 act as isolation features between the subsequently formed source/drain regions and the subsequently formed gate structures. Further, the inner spacers 236 may be used to substantially prevent damage to the subsequently formed source/drain regions by subsequent etching processes, such as etching processes used to subsequently remove the first semiconductor sheets 310. In some embodiments, the inner spacers 236 can be interchangeably referred to lower gate spacers. In some embodiments, the inner spacers 236 may have a lateral dimension in a range from about 4 nm to about 12 nm.

As an example to form the inner spacers 236, the source/drain recesses 94 can be laterally expanded. Specifically, portions of the sidewalls of the first semiconductor sheets 310 exposed by the source/drain recesses 94 may be recessed. Although sidewalls of the first semiconductor sheets 310 are illustrated as being straight, the sidewalls may be concave or convex. The sidewalls may be recessed by any acceptable etching process, such as one that is selective to the material of the first semiconductor sheets 310 (e.g., selectively etches the material of the first semiconductor sheets 310 at a faster rate than the material of the second semiconductor sheets 210). The etching may be isotropic. For example, when the second semiconductor sheets 210 are formed of silicon and the first semiconductor sheets 310 are formed of silicon germanium, the etching process may be a wet etch using tetramethylammonium hydroxide (TMAH), ammonium hydroxide (NH₄OH), or the like. In another embodiment, the etching process may be a dry etch using a fluorine-based gas such as hydrogen fluoride (HF) gas. In some embodiments, the same etching process may be continually performed to both form the source/drain recesses 94 and recess the sidewalls of the first semiconductor sheets 310. The inner spacers 236 can then be formed by conformally forming an insulating material and subsequently etching the insulating material. The insulating material may be silicon nitride or silicon oxynitride, although any suitable material, such as low-dielectric constant (low-k) materials having a k-value less than about 3.5, may be utilized. In some embodiments, the inner spacer 236 may have a higher K (dielectric constant) value than the gate spacer 233. In some embodiments, the material of inner spacer is selected from a group including SiO₂, Si₃N₄, SiON, SiOC, SiOCN base dielectric material, air gap, or combinations thereof. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 236 are illustrated as being flush with respect to the sidewalls of the gate spacers 233, the outer sidewalls of the inner spacers 236 may extend beyond or be recessed from the sidewalls of the gate spacers 233. In other words, the inner spacers 236 may partially fill, completely fill, or overfill the sidewall recesses. Moreover, although the sidewalls of the inner spacers 236 are illustrated as being straight, the sidewalls of the inner spacers 236 may be concave or convex.

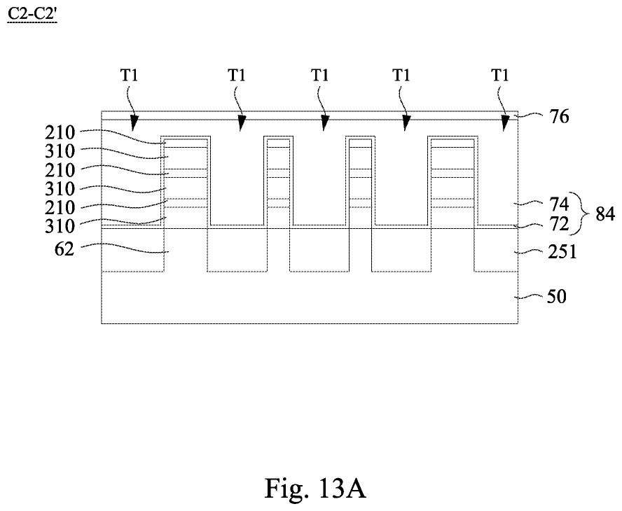

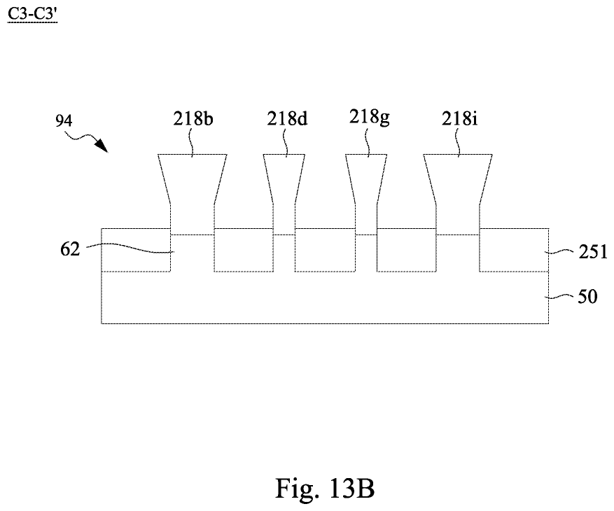

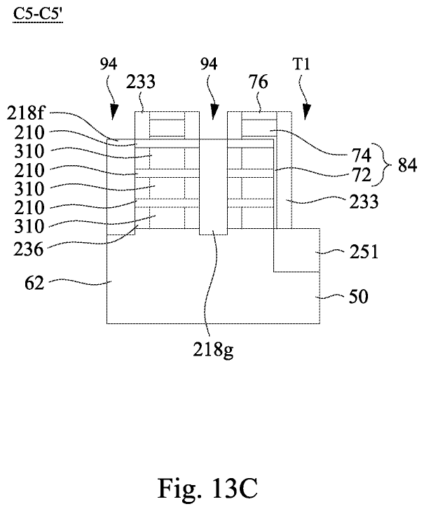

Reference is made to FIGS. 13A, 13B, and 13C. Eepitaxial source/drain regions 218a, 218b, 218d, 218f, 218g, 218h, 218i, and 218j are formed in the source/drain recesses 94, such that each dummy gate 84 (and corresponding channel regions) is disposed between respective adjacent pairs of the epitaxial source/drain regions 218a, 218b, 218d, 218f, 218g, 218h, 218i, and 218j. In some embodiments, the gate spacers 233 and the inner spacers 236 are used to separate the epitaxial source/drain regions 218a, 218b, 218d, 218f, 218g, 218h, 218i, and 218j from, respectively, the dummy gate structures 84 and the first semiconductor sheets 310 by an appropriate lateral distance so that the epitaxial source/drain regions 218a, 218b, 218d, 218f, 218g, 218h, 218i, and 218j do not short out with subsequently formed gates of the resulting nano-FETs. A material of the epitaxial source/drain regions 218a, 218b, 218d, 218f, 218g, 218h, 218i, and 218j may be selected to exert stress in the respective channel regions, thereby improving performance of the semiconductor structure.

The epitaxial source/drain regions 218a, 218b, 218h, 218i, and 218j in the first conductivity type device regions 10A and 10C may be formed by masking the second conductivity type device region 10B. Then, the epitaxial source/drain regions 218a, 218b, 218h, 218i, and 218j in the first conductivity type device regions 10A and 10C are epitaxially grown in the source/drain recesses 94 in the first conductivity type device regions 10A and 10C. The epitaxial source/drain regions 218a, 218b, 218h, 218i, and 218j may include any acceptable material appropriate for n-type devices. For example, the epitaxial source/drain regions 218a, 218b, 218h, 218i, and 218j in the first conductivity type device regions 10A and 10C may include materials exerting a tensile strain on the channel regions, such as silicon, silicon carbide, phosphorous doped silicon carbide, silicon phosphide, or the like. The epitaxial source/drain regions 218a, 218b, 218h, 218i, and 218j in the first conductivity type device regions 10A and 10C may be referred to as “n-type source/drain regions.” The epitaxial source/drain regions 218a, 218b, 218h, 218i, and 218j in the first conductivity type device regions 10A and 10C may have surfaces raised from respective surfaces of the fins 62 and the first and second semiconductor sheets 310, 210, and may have facets.

The epitaxial source/drain regions 218d, 218f, 218g in the second conductivity type device region 10B may be formed by masking the first conductivity type device regions 10A and 10C. Then, the epitaxial source/drain regions 218d, 218f, 218g in the second conductivity type device region 10B are epitaxially grown in the source/drain recesses 94 in the second conductivity type device region 10B. The epitaxial source/drain regions 218d, 218f, 218g may include any acceptable material appropriate for p-type devices. For example, the epitaxial source/drain regions 218d, 218f, 218g in the second conductivity type device region 10B may include materials exerting a compressive strain on the channel regions, such as silicon germanium, boron doped silicon germanium, germanium, germanium tin, or the like. The epitaxial source/drain regions 218d, 218f, 218g in the second conductivity type device region 10B may be referred to as “p-type source/drain regions.” The epitaxial source/drain regions 218d, 218f, 218g in the second conductivity type device region 10B may have surfaces raised from respective surfaces of the fins 62 and the first and second semiconductor sheets 310, 210, and may have facets.

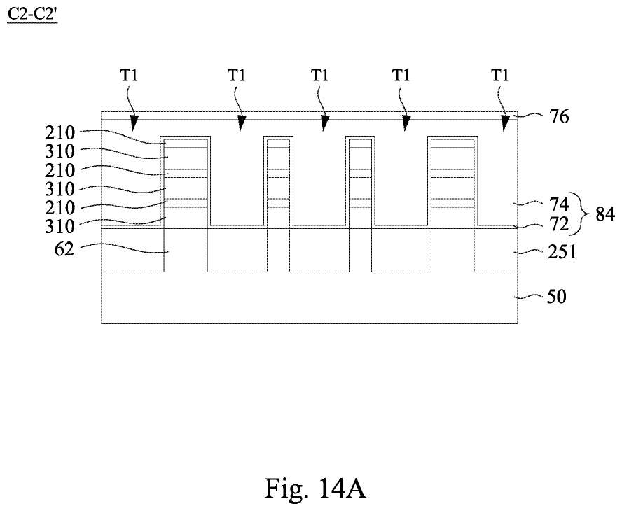

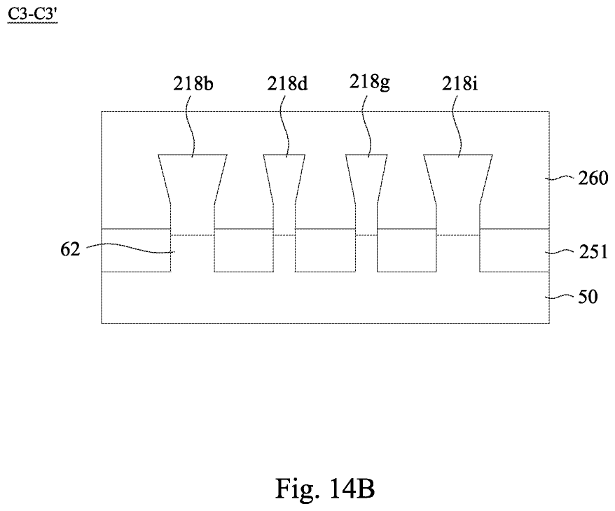

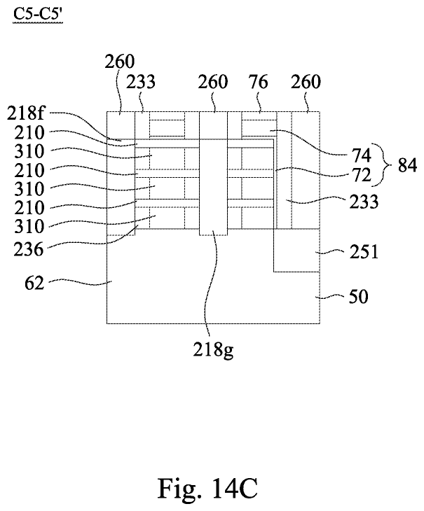

Reference is made to FIGS. 14A, 14B, and 14C. An inter-layer dielectric (ILD) layer 260 is deposited over the epitaxial source/drain regions 218a, 218b, 218d, 218f, 218g, 218h, 218i, and 218j, the gate spacers 233, the dummy gate structures 84. The ILD layer 260 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) is formed between the ILD layer 260 and the epitaxial source/drain regions 218a, 218b, 218d, 218f, 218g, 218h, 218i, and 218j, the gate spacers 233, and the dummy gate structures 84. The CESL may be formed of a dielectric material, such as silicon nitride, silicon oxide, silicon oxynitride, or the like, having a high etching selectivity from the etching of the ILD 260. The CESL may be formed by an any suitable method, such as CVD, ALD, or the like.

Subsequently, a removal process is performed to level the top surfaces of the ILD layer 260 with the top surfaces of the dummy gate structures 84. In some embodiments, a planarization process such as a chemical mechanical polish (CMP), an etch-back process, combinations thereof, or the like may be utilized. The planarization process may also remove the masks 76 on the dummy gate structures 84, and portions of the gate spacers 233 along sidewalls of the masks 76. After the planarization process, the top surfaces of the gate spacers 233, the ILD layer 260, the CESL, and the dummy gate structures 84 are coplanar (within process variations). Accordingly, the top surfaces of the dummy gate structures 84 are exposed through the ILD layer 260. In some embodiments, the masks 76 remain, and the planarization process levels the top surfaces of the ILD layer 260 with the top surfaces of the masks 76.

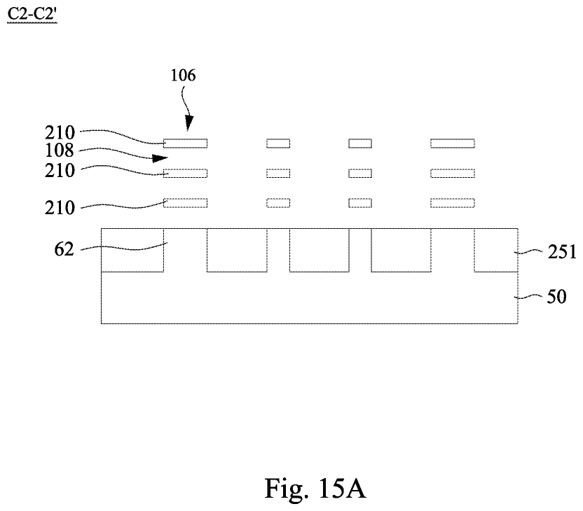

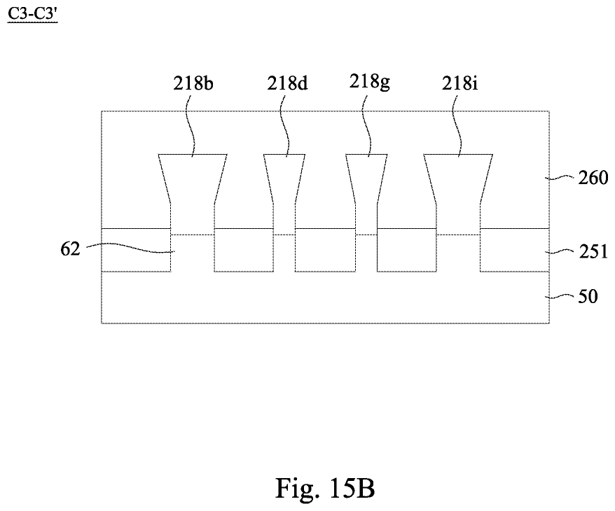

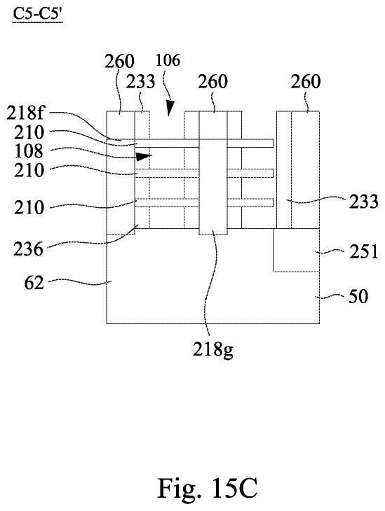

Reference is made to FIGS. 15A, 15B, and 15C. The dummy gate structures 84 are removed in an etching process, so that recesses 106 are formed. Portions of the dummy dielectrics 72 in the recesses 106 are also removed. In some embodiments, the dummy gate structures 84 are removed by an anisotropic dry etch process. For example, the etching process may include a dry etch process using reaction gas(es) that selectively etch the dummy gate structures 84 at a faster rate than the ILD layer 260 or the gate spacers 233. During the removal, the dummy dielectrics 72 may be used as etch stop layers when the dummy gate structures 84 are etched. The dummy dielectrics 72 are then removed. Each recess 106 exposes and/or overlies portions of the channel regions. Portions of the second semiconductor sheets 210 which act as the channel regions are disposed between adjacent pairs of the epitaxial source/drain regions 218a, 218b, 218d, 218f, 218g, 218h, 218i, and 218j.

The remaining portions of the first semiconductor sheets 310 are then removed to expand the recesses 106, such that openings 108 are formed in regions between the second semiconductor sheets 210. The remaining portions of the first semiconductor sheets 310 can be removed by any acceptable etching process that selectively etches the material of the first semiconductor sheets 310 at a faster rate than the material of the second semiconductor sheets 210. The etching may be isotropic. For example, when the first semiconductor sheets 310 are formed of silicon germanium and the second semiconductor sheets 210 are formed of silicon, the etching process may be a wet etch using tetramethylammonium hydroxide (TMAH), ammonium hydroxide (NH 4 OH), or the like. In some embodiments, a trim process (not separately illustrated) is performed to decrease the thicknesses of the exposed portions of the second semiconductor sheets 210. In some embodiments, the removing of the remaining portions of the first semiconductor sheets 310 can be interchangeably referred to as a channel releasing process. The second semiconductor sheets 210 can be interchangeably referred to as a vertically stacked multiple channels (sheets) and may have a vertically sheet pitch within a range of from about 10 nm to about 30 nm. In some embodiments, the second semiconductor sheets 210 may have a thickness within a range from about 4 nm to about 10 nm. In some embodiments, the vertically sheet pitch of the between adjacent two of the second semiconductor sheets 210 may be within a range from about 6 to about 20 nm.

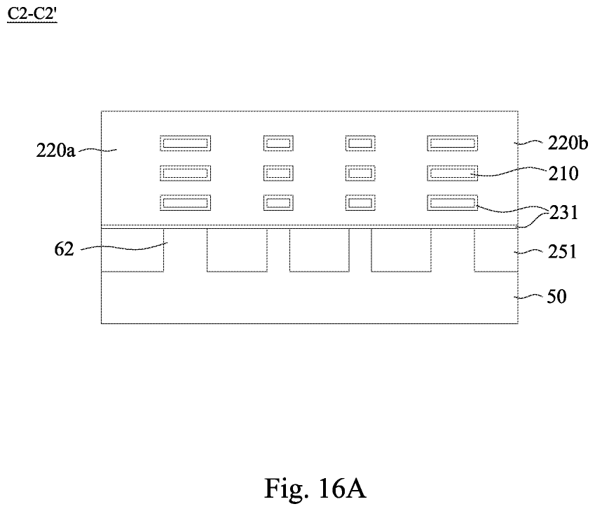

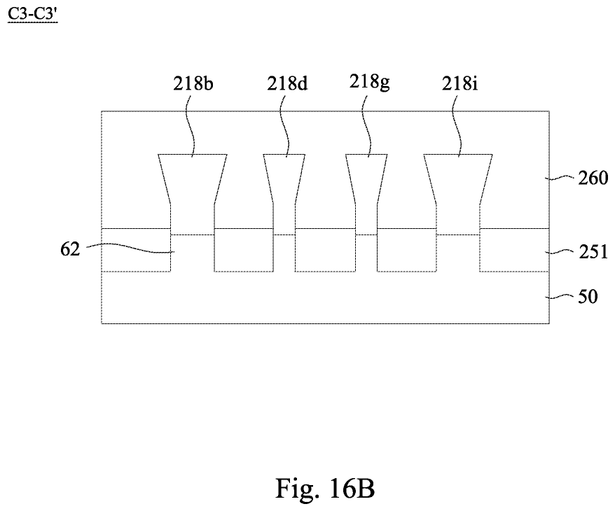

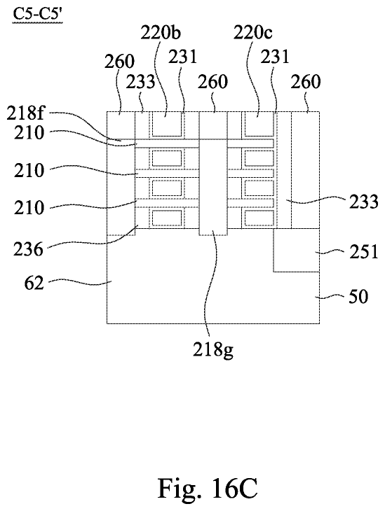

Reference is made to FIGS. 16A, 16B, and 16C. Gate structures are formed to wrap around the second semiconductor sheets 210. A gate dielectric layer 231 is formed in the recesses 106. Gate electrode layers 220a through 220d are formed on the gate dielectric layer 231. The gate dielectric layer 231 and the gate electrode layers 220a through 220d are layers for replacement gates, and each wrap around all (e.g., four) sides of the second semiconductor sheet 210. In some embodiments, the gate structure can be interchangeably referred to as a gate strip or a gate pattern.

The gate dielectric layer 231 is disposed on the sidewalls and/or the top surfaces of the fins 62; on the top surfaces, the sidewalls, and the bottom surfaces of the second semiconductor sheets 210; and on the sidewalls of the gate spacers 233. The gate dielectric layer 231 may include an oxide such as silicon oxide or a metal oxide, a silicate such as a metal silicate, combinations thereof, multi-layers thereof, or the like. The gate dielectric layer 231 may include a dielectric material having a k-value greater than about 7.0, such as a metal oxide or a silicate of hafnium, aluminum, zirconium, lanthanum, manganese, barium, titanium, lead, and combinations thereof. Although a single-layered gate dielectric layer 231 is illustrated in FIGS. 16A and 16C, as will be subsequently described in greater detail, the gate dielectric layer 231 may include any number of interfacial layers and any number of main layers.

The gate electrode layers 220a through 220d may include a metal-containing material such as titanium nitride, titanium oxide, tungsten, cobalt, ruthenium, aluminum, combinations thereof, multi-layers thereof, or the like. Although a single-layered gate electrode layers 220a through 220d is illustrated in FIGS. 16A and 16C, as will be subsequently described in greater detail, the gate electrode layer 220a through 220d may include any number of work function tuning layers, any number of barrier layers, any number of glue layers, and a fill material. In some embodiments, the gate electrode layers 220a through 220f may be made of a material selected from a group including TiN, TaN, TiAl, TiAlN, TaAl, TaAlN, TaAlC, TaCN, WNC, Co, Ni, Pt, W, or combinations thereof.

The formation of the gate dielectric layers 231 in the first conductivity type device regions 10A, 10C and the second conductivity type device region 10B may form simultaneously such that the gate dielectric layers 231 in each region are formed of the same materials, and the formation of the gate electrode layers 220a through 220d may form simultaneously such that the gate electrode layers 220a through 220d in each region are formed of the same materials. In some embodiments, the gate dielectric layers 231 in each region may be formed by distinct processes, such that the gate dielectric layers 231 may be different materials and/or have a different number of layers, and/or the gate electrode layers 220a through 220d in each region may be formed by distinct processes, such that the gate electrode layers 220a through 220d may be different materials and/or have a different number of layers. Various masking steps may be used to mask and expose appropriate regions when using distinct processes. In the following description, at least portions of the gate electrode layers 220a through 220d in the first conductivity type device regions 10A, 10C and the gate electrode layers 220a through 220d in the second conductivity type device region 10B are formed separately.

Subsequently, a removal process is performed to remove the excess portions of the materials of the gate dielectric layer 231 and the gate electrode layers 220a through 220d, which excess portions are over the top surfaces of the ILD layer 260 and the gate spacers 233, thereby forming gate dielectric layer 231 and gate electrode layers 220a through 220d. In some embodiments, a planarization process such as a chemical mechanical polish (CMP), an etch-back process, combinations thereof, or the like may be utilized. The gate dielectric layer 231, when planarized, has portions left in the recesses 106 (thus forming the gate dielectric layer 231). The gate electrode layers 220a through 220d, when planarized, have portions left in the recesses 106 (thus forming the gate electrode layers 220a through 220d). The top surfaces of the gate spacers 233; the CESL (not shown); the ILD layer 260; the gate dielectric layer 231, and the gate electrodes are coplanar (within process variations). The gate dielectric layer 231 and the gate electrode layers 220a through 220d form replacement gates of the resulting nano-FETs. Each respective pair of a gate dielectric layer 231 and a gate electrode layer 220a, 220b, 220c, or 220d may be collectively referred to as a “gate structure.” The gate structures each extend along top surfaces, sidewalls, and bottom surfaces of a channel region of the second semiconductor sheet 210. In some embodiments, the gate electrode layers 220a through 220d each have a gate length in a range from about 6 nm to about 20 nm.

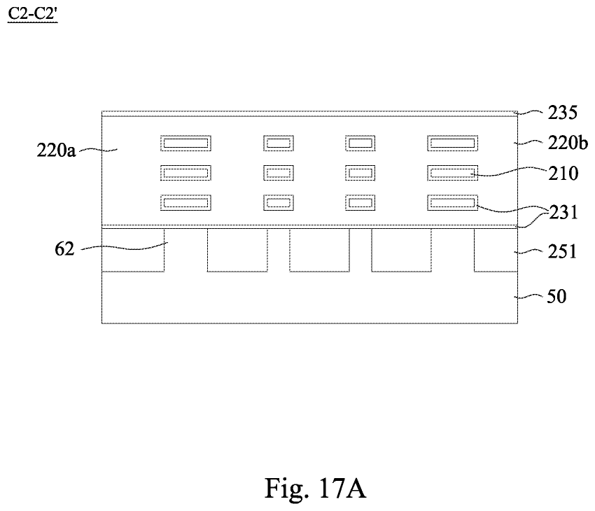

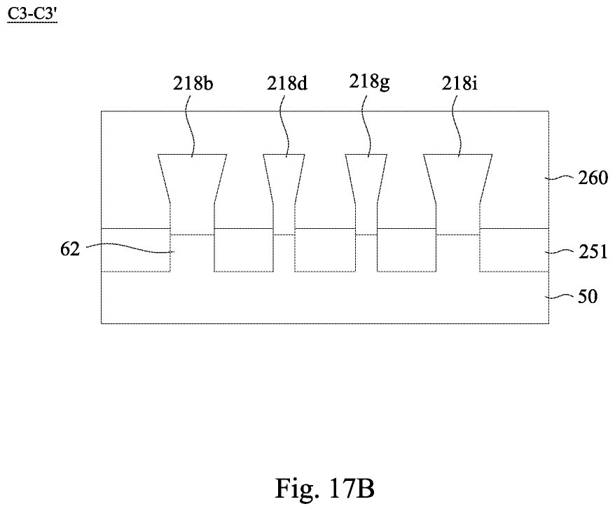

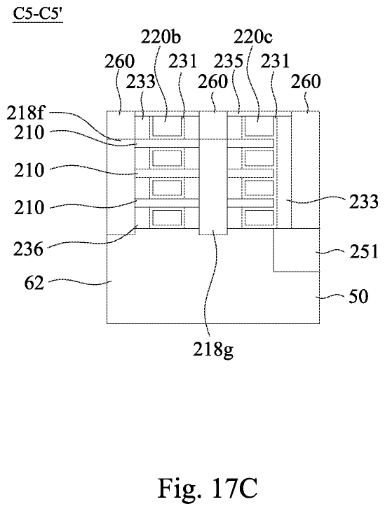

Reference is made to FIGS. 17A, 17B, and 17C. An etch back process is performed on the gate electrode layers 220a through 220d and the gate dielectric layer 231 to scale down the gate electrode layers 220a through 220d and the gate dielectric layer 231. The etch back process may include a bias plasma etching step. The bias plasma etching step may be performed to remove portions of the gate electrode layers 220a through 220d and the gate dielectric layer 231. Portions of the gate trenches may reappear with shallower depth. Top surfaces of the gate electrode layers 220a through 220d and the gate dielectric layer 231 may be no longer level with the ILD layer 260. Sidewalls of the gate spacers 233 are then exposed from the gate electrode layers 220a through 220d and the gate dielectric layer 231. In some embodiments, the bias plasma etching step may use a gas mixture of Cl₂, O₂, BCl₃, and Ar with a bias in a range from about 25V to about 1200V.

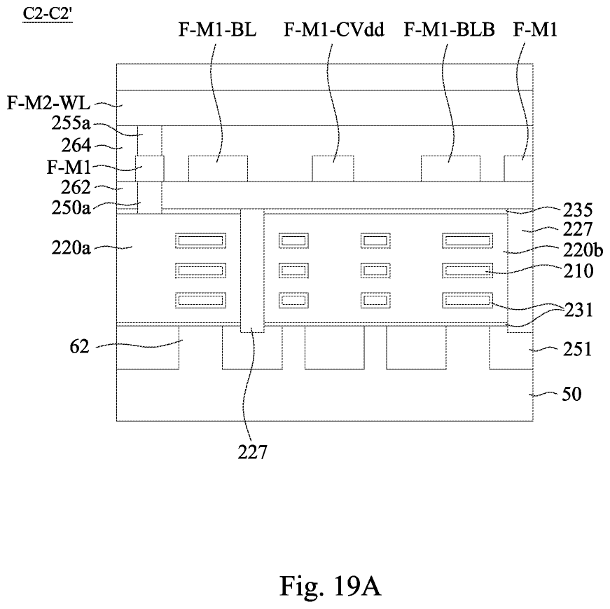

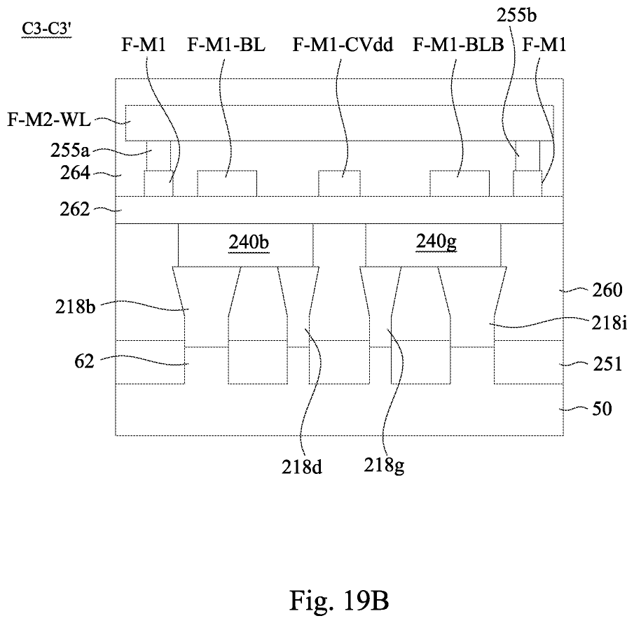

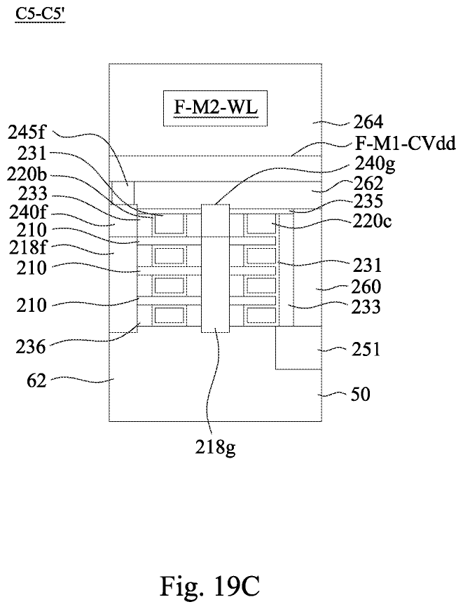

Subsequently, a hard mask layer 235 is formed over the gate electrode layers 220a through 220d and the gate dielectric layer 231 using, for example, a deposition process to deposit a dielectric material over the substrate 50, followed by a CMP process to remove excess dielectric material above the spacers 233 and the ILD layer 260. In some embodiments, source/drain contacts 240a through 240f (see FIGS. 19B and 19C) formed subsequently are formed by a self-aligned contact process using the hard mask layer 235 as a contact etch protection layer. In some embodiments, the hard mask layer 235 may have a thickness in a range from about 2 nm to about 60 nm.

In some embodiments, the hard mask layer 235 may be made of a nitride-based material, such as Si₃N₄, SiON, or a carbon-based material, such as SiC, SiOC, SiOCN, or combinations thereof. In some embodiments, the hard mask layer 235 may include SiOₓ, SiBN, SiCBN, other suitable dielectric materials, or combinations thereof. In some embodiments, the hard mask layer 235 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 235 has different etch selectivity than the spacers 233 and/or the ILD layer 260, so as to selective etch back the hard mask layer 235. By way of example, if the hard mask layer 235 is made of silicon nitride, the spacers 233 and/or the ILD layer 260 may be made of a dielectric material different from silicon nitride. If the hard mask layer 235 is made of silicon carbide (SiC), the spacers 233 and/or the ILD layer 260 may be made of a dielectric material different from silicon carbide. Therefore, the hard mask layer 235 can be used to define self-aligned gate contact region and thus referred to as a self-aligned contact (SAC) structure or a SAC layer.

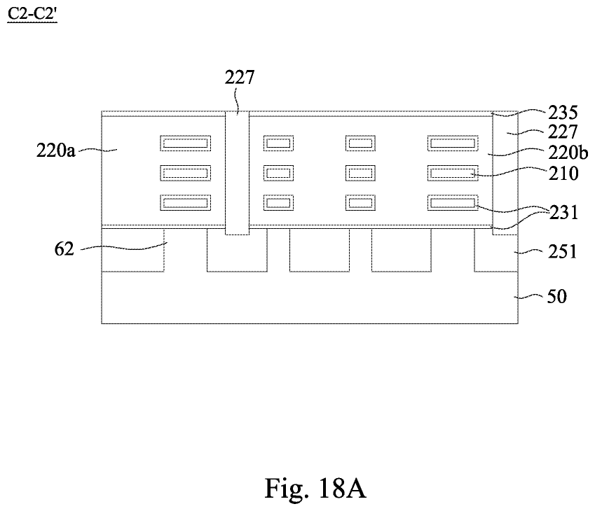

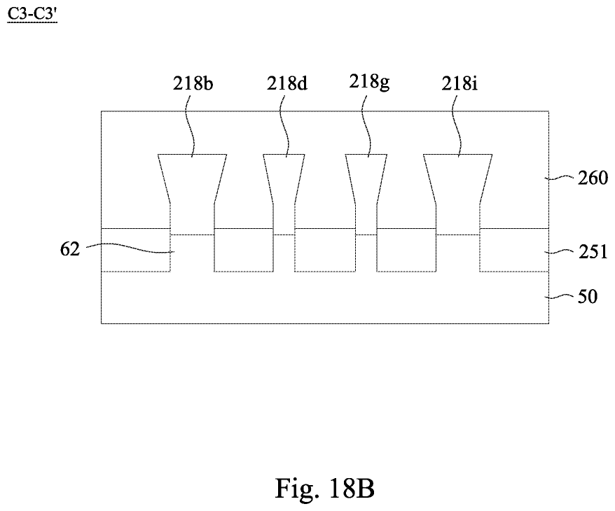

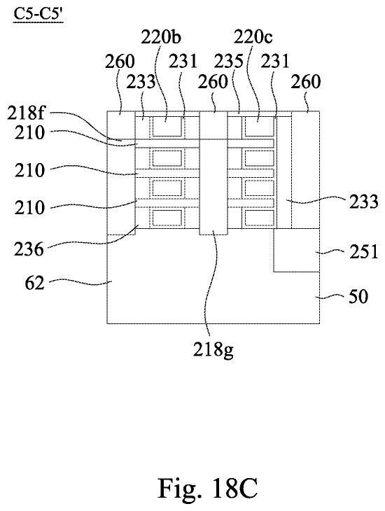

Reference is made to FIGS. 18A, 18B, and 18C. The dielectric regions 227 are formed on opposite ends of the gate electrode layers 220a through 220d. In some embodiments, each dielectric region 227 is a gate-cut structure for the gate structure, and the gate-cut structure is formed by a cut metal gate (CMG) process. In some embodiments, the dielectric region 227 can be interchangeably referred to a gate end dielectric. Specifically, the opposite ends the gate electrode layers 220a through 220d are removed to form gate trenches with the gate spacers 233 as their sidewalls. The ends of the gate electrode layers 220a through 220d may be removed by dry etching, wet etching, or a combination of dry and wet etching. For example, a wet etching process may include exposure to a hydroxide containing solution (e.g., ammonium hydroxide), deionized water, and/or other suitable etchant solutions. Subsequently, a dielectric material is deposited into the gate trenches, followed by a planarization process to remove excess portions of the dielectric material. The remaining dielectric material forms the dielectric regions 227.

In some embodiments, the deposition of the dielectric material of the dielectric regions 227 is performed using a conformal deposition process such as ALD, which may be PEALD, thermal ALD, or the like. The dielectric material may be formed of or comprise SiO₂, SiOC, SiOCN, or the like, or combinations thereof. In some embodiments, the dielectric region 227 may be made of a nitride-based material, such as Si₃N₄, or a carbon-based material, such as SiOCN, or combinations thereof. In some embodiments, the dielectric region 227 may be made of a material having a dielectric constant greater than about 9 (e.g., high dielectric constant (high-k) material). For example, the dielectric region 227 may be made of a high dielectric constant (high-k) material, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The dielectric regions 227 may be formed of a homogenous material, or may have a composite structure including more than one layer. The dielectric regions 227 may include dielectric liners, which may be formed of, for example, silicon oxide. In some embodiments, the dielectric material of the dielectric regions 227 comprises SiN, and the deposition is performed using process gases including dichlorosilane and ammonia. Hydrogen (H₂) may or may not be added.

Reference is made to FIGS. 19A, 19B, and 19C. Source/drain contacts 240a through 240f are formed in the ILD layer 260 and on the source/drain regions 218a, 218b, 218d, 218e, 218f, 218g, 218i, and 218j. In some embodiments, the source/drain vias 245a, 245c, 245d, and 245f are formed in an ILD layer 262 to land on the source/drain contacts 240a, 240c, 240d, and 240f, respectively. Gate vias 250a and 250d are formed to pass through the ILD layer 262 and the hard mask layer 235 and land on the gate electrode layers 220a and 220d, respectively. The source/drain contacts 240a through 240f, the source/drain vias 245a, 245c, 245d, and 245f, and the gate vias 250a and 250d may include a metal-containing material such as titanium nitride, titanium oxide, tungsten, cobalt, ruthenium, aluminum, copper, combinations thereof, multi-layers thereof, or the like. The ILI) layer 262 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Subsequently, a front-side interconnect structure is formed over the front-side gate via and the front-side source/drain via. The interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The front-side interconnect structure may include the power supply voltage lines F-M1-CVdd, the bit-line F-M1-BL, the bit-line-bar F-M1-BLB in a first front-side metallization layer and word-lines F-M2-WL in a second front-side metallization layer. The power supply voltage lines F-M1-CVdd, the bit-line F-M1-BL, the bit-line-bar F-M1-BLB, and word-lines F-M2-WL are in an IMD (inter-metal dielectric) layer 264. The front-side metal layers F-M1 are electrically connected to the gate electrode layers 220a and 220d through the gate vias 250. The power supply voltage lines F-M1-CVdd, the bit-line F-M1-BL, the bit-line-bar F-M1-BLB are electrically connected to the source/drain contacts 240a, 240c, 240d, and 240f through the source/drain vias 245a, 245c, 245d, and 245f. The front-side interconnect structure further includes conductive vias 255a, 255b in the IMD layer 264. In some embodiments, the conductive vias 255a, 255b are connected between the first front-side metallization layer and a second front-side metallization layer over the first metallization layer. For example, the front-side metal layers F-M1 are connected to an overlying level (e.g., word-line F-M2-WL) through the vias 255a, 255b. In some embodiments, materials of the power supply voltage lines F-M1-CVdd, the bit-line F-M1-BL, the bit-line-bar F-M1-BLB, word-lines F-M2-WL, the gate vias 250a and 250d. the source/drain vias 245a, 245c, 245d, and 245f, the conductive vias 255a, 255b, and the source/drain contacts 240a through 240f may include Cu, Co, Ru, Pt, Al, W, Ti, TaN, TiN, or any combinations thereof. In some embodiments, the IMD layer 264 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

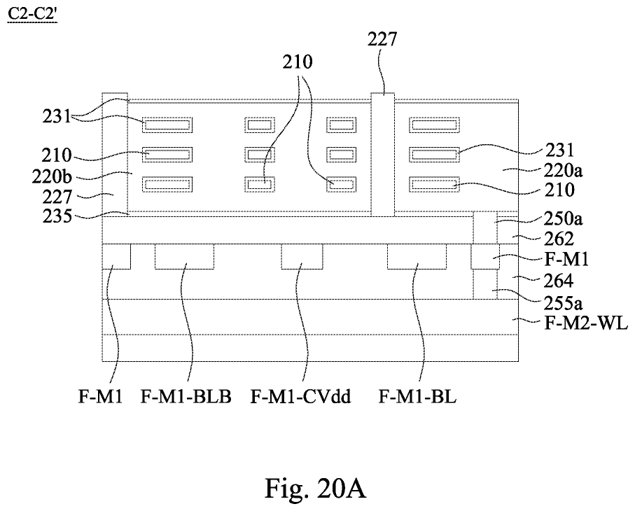

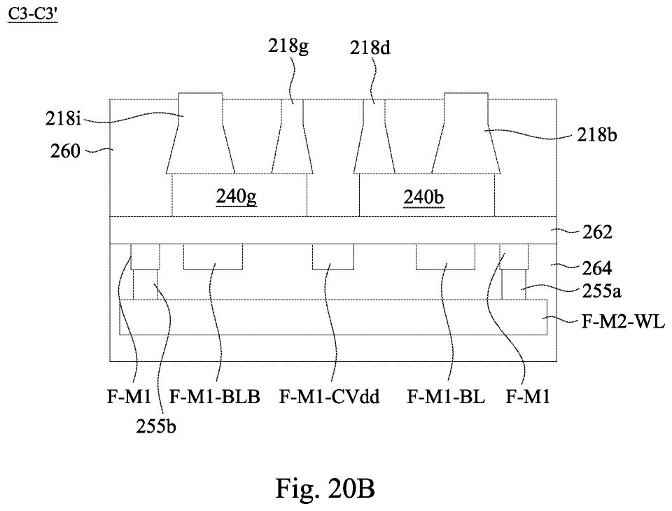

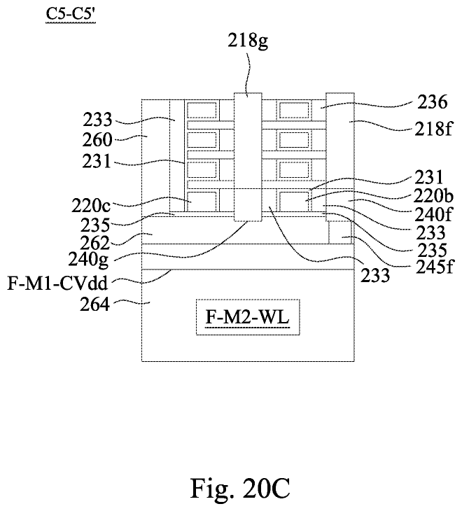

Reference is made to FIGS. 20A, 20B, and 20C. The structures of FIGS. 19A-19C are “flipped” upside down, and the substrate 50 and the STI structure 251 are removed. The substrate 50, the fins 62, and portions of the STI structure 251 may be removed in a plurality of process operations, for example, CMP, HNA, and/or TMAH etching, which stops at the source/drain regions 218a through 218j. Subsequently, remainders of the fins 62 are removed. Subsequently, the remaining portions of the STI structure 251 can be removed by any acceptable etching process that selectively etches the material of the STI structure 251 at a faster rate than the material of the source/drain regions 218a through 218j, the inner spacers 236, and/or the gate dielectric layer 231. The etching may be isotropic, such as a wet etch. After the removal process, the source/drain regions 218a through 218j, the inner spacers 236, and/or the gate dielectric layer 231 are exposed as shown in FIGS. 20A, 20B, and 20C.

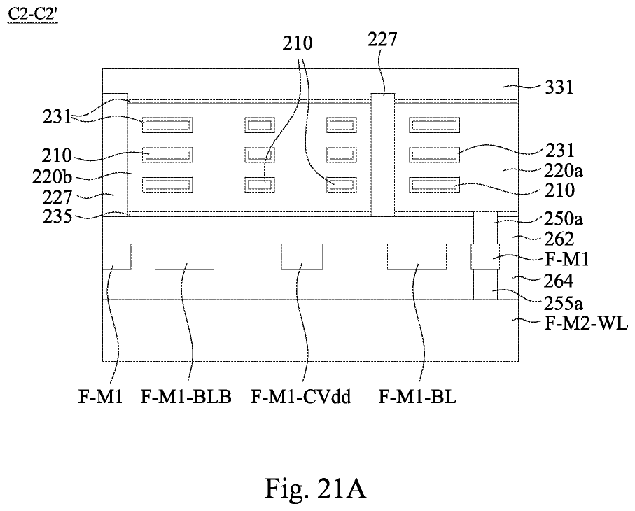

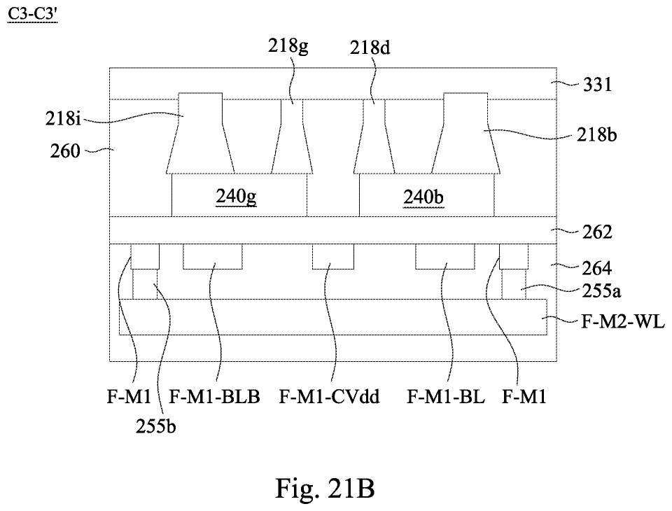

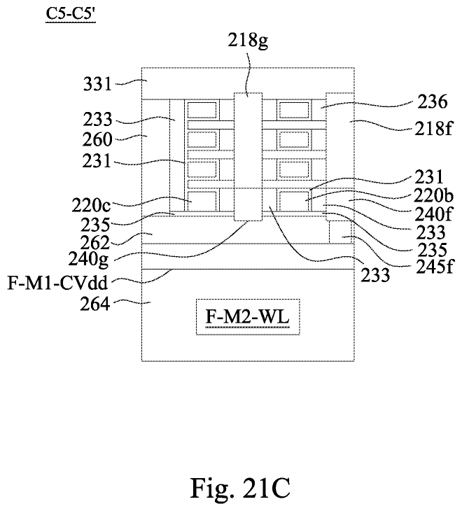

Reference is made to FIGS. 21A, 21B, and 21C. A back-side dielectric 331 is formed over the STI structures 251, the source/drain regions 218a through 218j, the inner spacers 236, and/or the gate dielectric layer 231. The back-side dielectric 331 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

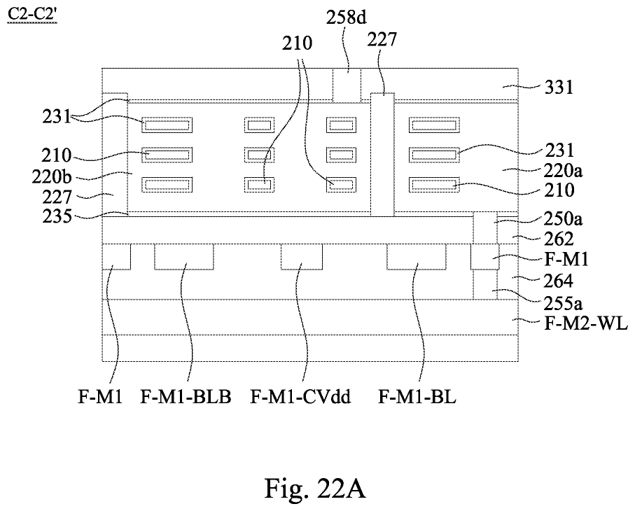

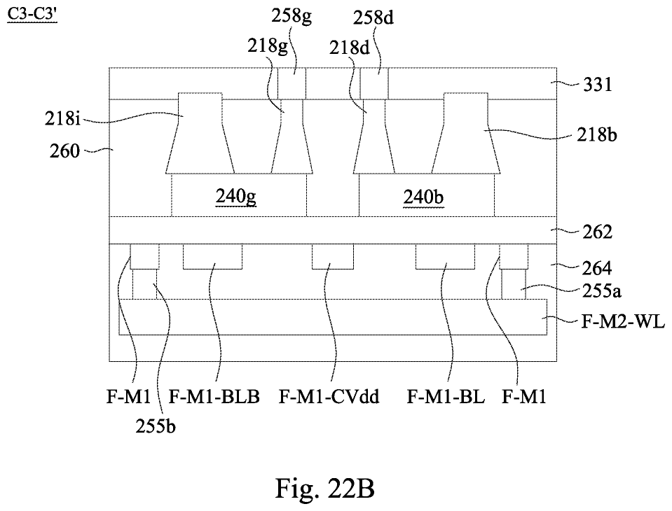

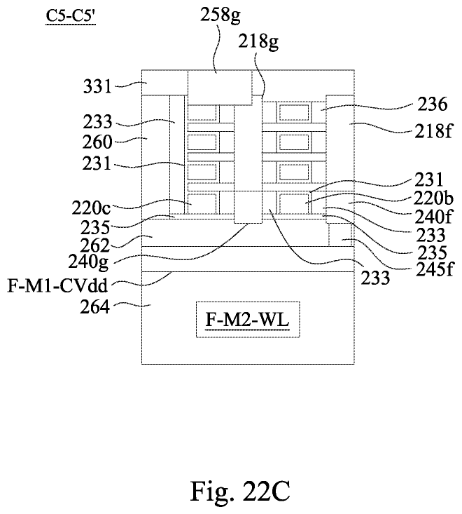

Reference is made to FIGS. 22A, 22B, and 22C. The back-side conductive vias 259a, 259b are formed in the back-side dielectric 331 and on the source/drain regions 218c, 218h. The back-side butt contact 258d is formed in the back-side dielectric 331 and on the source/drain regions 218d and the gate electrode layer 220b. The back-side butt contact 258g is formed in the back-side dielectric 331 and on the source/drain regions 218g and the gate electrode layer 220c. The back-side butt contacts 258d and 258g can be fabricated simultaneously with back-side conductive vias 259a, 259b in a same process, and thus fabrication of the back-side butt contacts 258d and 258g will not result in additional processes and hence additional cost and without additional metal materials and masks. In some embodiments, the back-side conductive vias 259a, 259b can be interchangeably referred to back-side source/drain vias. In some embodiments, the back-side conductive vias 259a, 259b and the back-side butt contacts 258d, 258g may be made of a metal-containing material such as titanium nitride, titanium oxide, tungsten, cobalt, ruthenium, aluminum, copper, combinations thereof, multi-layers thereof, or the like.

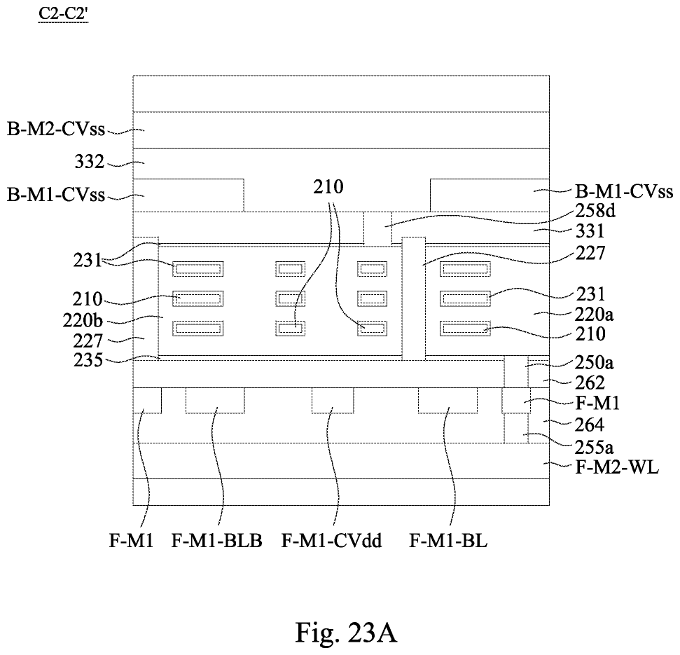

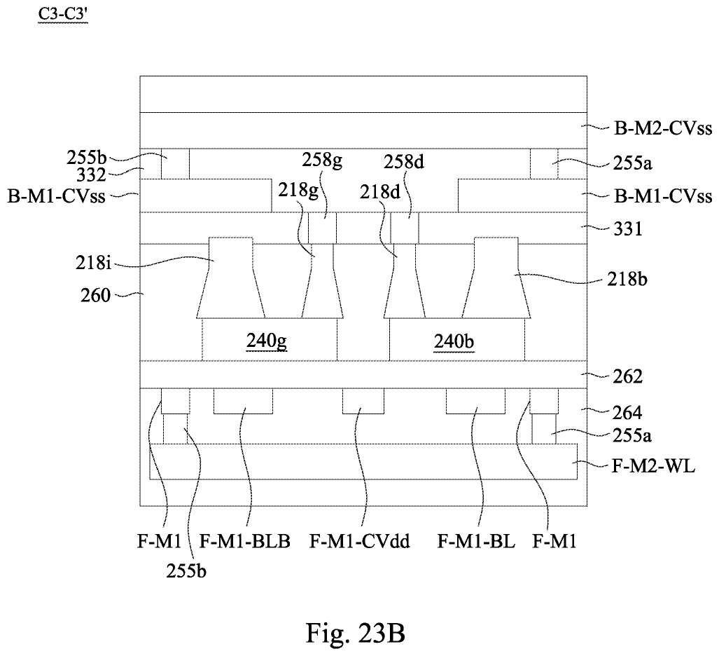

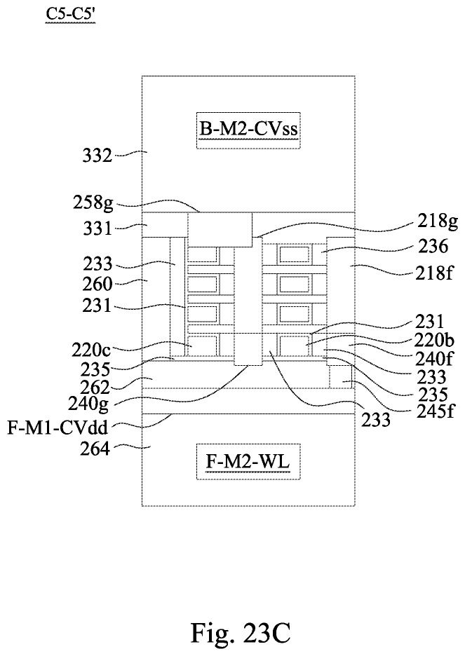

Reference is made to FIGS. 23A, 23B, and 23C. A back-side interconnect structure is formed over the back-side conductive vias source/drain contact. The back-side interconnect structure includes a plurality of metallization layers with a plurality of metallization vias or interconnects. Other embodiments may contain more or fewer metallization layers and corresponding more or fewer number of vias. The metal line illustrated here just for an example, and the metal line may be otherwise oriented (rotated 90 degrees or at other orientations). The back-side interconnect structure may include the power supply voltage lines B-M1-CVss, B-M2-CVss in first and second back-side metallization layers. The power supply voltage lines B-M1-CVss, B-M2-CVss are formed in an IMD layer 332. The power supply voltage lines B-M1-CVss are electrically connected to the source/drain regions 218c, 218h through the back-side conductive vias 259a, 259b. The back-side interconnect structure further includes back-side conductive vias 257a, 257b in an IMD layer 332. In some embodiments, the conductive vias 257a, 257b are connected between the first back-side metallization layer and a second back-side metallization layer over the first back-side metallization layer. For example, the power supply voltage lines B-M1-CVss in the first back-side metallization layers are connected to the power supply voltage lines B-M2-CVss through the vias 257a, 257b. In some embodiments, materials of the power supply voltage lines B-M1-CVss, B-M2-CVss may include Cu, Co, Ru, Pt, Al, W, Ti, TaN, TiN, or any combinations thereof. In some embodiments, the IMD layer 332 may be formed of an oxide such as Phospho-Silicate Glass (PSG), Boro-Silicate Glass (BSG), Boron-Doped Phospho-Silicate Glass (BPSG), Tetra Ethyl Ortho Silicate (TEOS) oxide, or the like.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a metal line routing method to improve the functional density and operation performance on the IC structure. Specifically, the front-side M1 level may include bit-line, bit-line-bar, and power supply voltage line. On the other hands, the front-side M1 level may be free of word-line. Therefore, the bit-line and bit-line-bar can be disposed in a lower metal layer to lower the resistance and the capacitance of the SRAM cell, such that the speed of SRAM cell can be improved. In addition, the power supply voltage line CVdd located on wafer front-side is connected to power supply voltage line CVdd located on wafer back-side through a tapping structure located within an edge cell of the SRAM cell array, and further connected to chip bond pads located on wafer back-side rather than on wafer front-side, such that IR drop of the IC structure can be reduced. Furthermore, the butt contacts connecting the source/drain region and the gate electrode layer can be disposed on wafer back-side, and thus the back-side butt contacts can be fabricated simultaneously with back-side conductive via in a same process, and thus fabrication of the back-side butt contacts will not result in additional processes and hence additional cost and without additional metal materials and masks.

In some embodiments, a method includes forming a static random access memory (SRAM) array comprising a plurality of SRAM cells, at least one of the SRAM cells comprising first and second pull-up transistors, first and second pull-down transistors, and first and second pass-gate transistors; forming a first front-side metal layer above the SRAM array, the first front-side metal layer comprising a first power supply voltage line and a bit-line, the first power supply voltage line electrically coupled to the first and second pull-up transistors, and the bit-line electrically coupled to the first pass-gate transistor; forming a back-side butt contact extending from a back-side of a gate structure of the first pull-up transistor to a back-side of a source/drain region of the second pull-up transistor from a cross sectional view. In some embodiments, the method further includes forming a source/drain contact on a source/drain region of the first pass-gate transistor; forming a source/drain via on the source/drain contact, the source/drain via being in contact with the bit-line. In some embodiments, the method further includes forming a second front-side metal layer above the first front-side metal layer, the second front-side metal layer comprising a word-line electrically coupled to the first pass-gate transistor; forming a first back-side metal layer below the SRAM array, the first back-side metal layer comprising a second power supply voltage line electrically coupled to the first pull-down transistor; forming a second back-side metal layer below the first back-side metal layer, the second back-side metal layer comprising a second power supply voltage line connecting to the second power supply voltage line. In some embodiments, the first front-side metal layer is free of word-lines. In some embodiments, the second front-side metal layer is free of power supply voltage lines. In some embodiments, the first front-side metal layer further comprises a second power supply voltage line electrically coupled to the first pull-down and pass-gate transistors, and the method further includes forming a second front-side metal layer above the first front-side metal layer, the second front-side metal layer comprising a third power supply voltage line connecting to the second power supply voltage line; forming a first back-side metal layer below the SRAM array, the first back-side metal layer comprising a first word-line electrically coupled to the pass-gate transistor; forming a second back-side metal layer below the first back-side metal layer, the second back-side metal layer comprising a second word-line connecting to the first word-line. In some embodiments, the first and second front-side metal layers are free of word-lines. In some embodiments, the first back-side metal layer further comprises a fourth power supply voltage line. In some embodiments, the second back-side metal layer is free of power supply voltage lines. In some embodiments, the method further includes forming a SRAM edge-cell region abutting the SRAM array, the SRAM edge-cell region comprising a plurality of dummy gate structures; forming a tap structure downwardly extending from the first power supply voltage line in the first front-side metal layer passing a positon laterally between the dummy gate structures to a second power supply voltage line formed below the SRAM array.

In some embodiments, a method includes forming first and second channel patterns over a substrate; forming a first gate pattern extending across the first channel pattern, and a second gate pattern extending across the second channel pattern from a top view; forming first source/drain patterns on the first channel pattern and at opposite sides of the first gate pattern, and second source/drain patterns on the second channel pattern and at opposite sides of second gate pattern from the top view; forming a front-side contact on a front-side of a first one of the first source/drain patterns from a cross sectional view; forming a back-side butt contact extending from a back-side of the first one of the first source/drain patterns to a back-side of the second gate pattern from the cross sectional view. In some embodiments, the method further includes forming a third channel pattern on the substrate, wherein the first gate pattern further extends across the third channel pattern; forming third source/drain patterns on the third channel pattern and at opposite sides of the first gate pattern; forming a back-side conductive via on one of the third source/drain patterns, a back-side surface of the back-side conductive via being level with a back-side surface of the back-side butt contact. In some embodiments, the method further includes forming a third channel pattern on the substrate; forming a third gate pattern extending across the third channel pattern, the first gate pattern also extending across the third channel pattern; forming third source/drain patterns on the third channel pattern and at opposite sides of the third gate pattern; forming a front-side power supply voltage line connecting to a second one of the first source/drain patterns; forming a front-side bit-line connecting to one of the third source/drain patterns, the front-side bit-line being at a same level height as the front-side power supply voltage line. In some embodiments, the first channel pattern, the first gate pattern, and the first source/drain patterns form a transistor being of a first inverter, and the second channel pattern, the second gate pattern, and the second source/drain patterns form a transistor being of a second inverter. In some embodiments, the first channel pattern, the first gate pattern, and the first source/drain patterns form a gate all around (GAA) transistor, and the second channel pattern, the second gate pattern, and the second source/drain patterns form a second GAA transistor.

In some embodiments, the semiconductor structure includes a memory array, and a first front-side metal layer, a second front-side metal layer. The memory array includes a plurality of memory cells. At least one of the memory cells includes first and second inverters. The first inverter includes a first pull-up transistor and a first pull-down transistor, and the second inverter includes a second pull-up transistor and a second pull-down transistor. The first front-side metal layer is above the memory array and includes a first power supply voltage line, a bit-line, and a bit-line bar, the first front-side metal layer being free of word-lines. The second front-side metal layer is at a higher level height than the first front-side metal layer and is free of bit-lines and bit-line-bars. In some embodiments, the second front-side metal layer comprises a word-line. In some embodiments, the semiconductor structure further includes a back-side butt contact extending from a back-side of a gate electrode of the first pull-up transistor to a back-side of a source/drain region of the second pull-up transistor from a cross sectional view. In some embodiments, the semiconductor structure further includes a back-side conductive via on a back-side of a source/drain region of the first pull-down transistor, a back-side surface of the back-side conductive via being level with a back-side surface of the back-side butt contact. In some embodiments, the semiconductor structure further includes an edge cell region and a tap structure. The edge cell region abuts the memory array and incudes a plurality of dummy gate structures. The tap structure downwardly extends from the first power supply voltage line in the first front-side metal layer passing a positon laterally between the dummy gate structures to a second power supply voltage line formed below the memory array.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a static random access memory (SRAM) array comprising a plurality of SRAM cells, at least one of the SRAM cells comprising first and second pull-up transistors, first and second pull-down transistors, and first and second pass-gate transistors;
forming a first front-side metal layer above the SRAM array, the first front-side metal layer comprising a first power supply voltage line and a bit-line, the first power supply voltage line electrically coupled to the first and second pull-up transistors, and the bit-line electrically coupled to the first pass-gate transistor; and
forming a back-side butt contact extending from a back-side of a gate structure of the first pull-up transistor to a back-side of a source/drain region of the second pull-up transistor from a cross sectional view.

2. The method of claim 1, further comprising:
forming a source/drain contact on a source/drain region of the first pass-gate transistor; and
forming a source/drain via on the source/drain contact, the source/drain via being in contact with the bit-line.

3. The method of claim 1, further comprising:
forming a second front-side metal layer above the first front-side metal layer, the second front-side metal layer comprising a word-line electrically coupled to the first pass-gate transistor;
forming a first back-side metal layer below the SRAM array, the first back-side metal layer comprising a second power supply voltage line electrically coupled to the first pull-down transistor; and
forming a second back-side metal layer below the first back-side metal layer, the second back-side metal layer comprising a second power supply voltage line connecting to the second power supply voltage line.

4. The method of claim 3, wherein the first front-side metal layer is free of word-lines.

5. The method of claim 3, wherein the second front-side metal layer is free of power supply voltage lines.

6. The method of claim 1, wherein the first front-side metal layer further comprises a second power supply voltage line electrically coupled to the first pull-down and pass-gate transistors, and the method further comprising:
forming a second front-side metal layer above the first front-side metal layer, the second front-side metal layer comprising a third power supply voltage line connecting to the second power supply voltage line;
forming a first back-side metal layer below the SRAM array, the first back-side metal layer comprising a first word-line electrically coupled to the pass-gate transistor; and
forming a second back-side metal layer below the first back-side metal layer, the second back-side metal layer comprising a second word-line connecting to the first word-line.

7. The method of claim 6, wherein the first and second front-side metal layers are free of word-lines.

8. The method of claim 6, wherein the first back-side metal layer further comprises a fourth power supply voltage line.

9. The method of claim 8, wherein the second back-side metal layer is free of power supply voltage lines.

10. The method of claim 1, further comprising:
forming a SRAM edge-cell region abutting the SRAM array, the SRAM edge-cell region comprising a plurality of dummy gate structures; and
forming a tap structure downwardly extending from the first power supply voltage line in the first front-side metal layer passing a positon laterally between the dummy gate structures to a second power supply voltage line formed below the SRAM array.

11. A method, comprising:
forming first and second channel patterns over a substrate;
forming a first gate pattern extending across the first channel pattern, and a second gate pattern extending across the second channel pattern from a top view;
forming first source/drain patterns on the first channel pattern and at opposite sides of the first gate pattern, and second source/drain patterns on the second channel pattern and at opposite sides of second gate pattern from the top view;
forming a front-side contact on a front-side of a first one of the first source/drain patterns from a cross sectional view; and
forming a back-side butt contact extending from a back-side of the first one of the first source/drain patterns to a back-side of the second gate pattern from the cross sectional view.

12. The method of claim 11, further comprising:
forming a third channel pattern on the substrate, wherein the first gate pattern further extends across the third channel pattern;
forming third source/drain patterns on the third channel pattern and at opposite sides of the first gate pattern; and
forming a back-side conductive via on one of the third source/drain patterns, a back-side surface of the back-side conductive via being level with a back-side surface of the back-side butt contact.

13. The method of claim 11, further comprising:
forming a third channel pattern on the substrate;
forming a third gate pattern extending across the third channel pattern, the first gate pattern also extending across the third channel pattern;
forming third source/drain patterns on the third channel pattern and at opposite sides of the third gate pattern;
forming a front-side power supply voltage line connecting to a second one of the first source/drain patterns; and
forming a front-side bit-line connecting to one of the third source/drain patterns, the front-side bit-line being at a same level height as the front-side power supply voltage line.

14. The method of claim 11, wherein the first channel pattern, the first gate pattern, and the first source/drain patterns form a transistor being of a first inverter, and the second channel pattern, the second gate pattern, and the second source/drain patterns form a transistor being of a second inverter.

15. The method of claim 11, wherein the first channel pattern, the first gate pattern, and the first source/drain patterns form a gate all around (GAA) transistor, and the second channel pattern, the second gate pattern, and the second source/drain patterns form a second GAA transistor.

16. A semiconductor structure, comprising:
a memory array comprising a plurality of memory cells, at least one of the memory cells comprising first and second inverters, the first inverter comprising a first pull-up transistor and a first pull-down transistor, and the second inverter comprising a second pull-up transistor and a second pull-down transistor;
a first front-side metal layer above the memory array, the first front-side metal layer comprising a first power supply voltage line, a bit-line, and a bit-line bar, the first front-side metal layer being free of word-lines; and
a second front-side metal layer at a higher level height than the first front-side metal layer, the second front-side metal layer being free of bit-lines and bit-line-bars.

17. The semiconductor structure of claim 16, wherein the second front-side metal layer comprises a word-line.

18. The semiconductor structure of claim 16, further comprising:
a back-side butt contact extending from a back-side of a gate electrode of the first pull-up transistor to a back-side of a source/drain region of the second pull-up transistor from a cross sectional view.

19. The semiconductor structure of claim 18, further comprising:
a back-side conductive via on a back-side of a source/drain region of the first pull-down transistor, a back-side surface of the back-side conductive via being level with a back-side surface of the back-side butt contact.

20. The semiconductor structure of claim 16, further comprising:
an edge cell region abutting the memory array, the edge cell region comprising a plurality of dummy gate structures; and
a tap structure downwardly extending from the first power supply voltage line in the first front-side metal layer passing a positon laterally between the dummy gate structures to a second power supply voltage line formed below the memory array.
